(19) United States
(12) Patent Application Publication
(10) Pub. No.: US 2012/0314483 A1
(43) Pub. Date: Dec. 13, 2012

(54) SEMICONDUCTOR DEVICE

(75) Inventor: Shuichi TSUKADA, Tokyo (JP)

(73) Assignee: Elpida Memory, Inc., Tokyo (JP)

(21) Appl. No.: 13/485,722

(22) Filed: May 31, 2012

(30) Foreign Application Priority Data
Jun. 8, 2011 (JP) 2011-128542

(51) Int. Cl. G11C 7/06; G11C 11/24; G11C 7/00

(52) U.S. Cl. 365/149; 365/189.011; 365/207

(57) ABSTRACT

A semiconductor device includes a bit line, a memory cell, and a control circuit. The memory cell includes a switch circuit coupled to the bit line and a memory element configured to store either one of first and second data. The control circuit controls a voltage of the bit line to turn on the switch element in a first time period and to turn off the switch element in a second time period following the first time period when the control circuit writes the first data to the memory element. The control circuit controls the voltage of the bit line to turn on the switch element in the first time period and to maintain an on-state of the switch circuit in the second time period when the control circuit writes the second data to the memory element.

This application is based upon and claims the benefit of the priority of Japanese patent application No. 2011-128542, filed on Jun. 8, 2011, the disclosure of which is incorporated herein in its entirety by reference thereto.

The present invention relates to a semiconductor device. In particular, it relates to a thyristor memory or an FBC (Floating Body Cell) memory storing a charge in a floating body, which is a semiconductor region that can be brought in a floating state.

### BACKGROUND

### Description of the Related Art

For example, thyristor and FBC memories are being proposed as alternatives to DRAMs, which are dominantly used as main memories. These thyristor and FBC memories record information by storing charges at a floating body node. Non-Patent Document 1 discloses a thyristor memory, and Patent Document 1 discloses an FBC memory.

FIG. 23A is an equivalent circuit diagram of a memory cell of a general thyristor memory as disclosed in Non-Patent Document 1. The memory cell includes an NMOS transistor M1 that has a substrate connected to a node FB and has a P-type drain semiconductor region connected to a node FN. In this way, since a PNP bipolar transistor Q2 and a parasitic NPN bipolar transistor Q1 are formed, a thyristor structure is formed. The PNP bipolar transistor Q2 has a base connected to the N-type region node FN and an emitter connected to a bit line BL (anode). In addition, the NMOS transistor M1 has a gate connected to a word line WL and a source connected to a VSS (cathode). When the memory cell is not selected, the node FB is in a floating state, and a charge is stored in a gate capacitor between the gate of the NMOS transistor M1 and the node FB. In this way, the memory cell executes memory operations.

FIG. 23B is an equivalent circuit diagram of a cell of a general FBC memory as disclosed in Patent Document 1. The cell includes an NMOS transistor M1 having a substrate connected to a node FB. The cell further includes a parasitic NPN bipolar transistor Q1. The NMOS transistor M1 has a drain connected to a bit line BL (drain), a gate connected to a word line WL, and a source connected to a VSS (source). When the cell is not selected, the node FB is in a floating state, and a charge is stored in a gate capacitor between the gate of the NMOS transistor M1 and the node FB. In this way, the cell executes memory operations.

FIG. 24 is an operation waveform diagram of a conventional thyristor memory cell. In FIG. 24, the horizontal axis represents time t and the vertical axis represents voltage V. Bit line waveforms representing data 1 and 0 are indicated by BL “1” (solid line) and BL “0” (dashed line), respectively. In addition, floating body voltages illustrating data 1 and 0 are indicated by FB “1” (solid line) and FB “0” (dotted line), respectively. As illustrated in FIG. 24, first, data is written in the memory cell between timing T1 and timing T4, and next, the data is read between timing T5 and timing T8. When data is written in the memory cell, the word line voltage is increased from a word line standby voltage VWLS to a word line write voltage VWLW. However, depending on the write data, the bit line is set to a different voltage level. More specifically, when data 1 is written in the memory cell, the bit line is set to a high level (VBL). When data 0 is written, the bit line is maintained at a low level (VSS).

When data is read from the memory cell, the bit line is set to a high level (VBL), and the word line voltage is increased from the word line standby voltage VWLS to a word line read voltage VWLR. The word line read voltage VWLR is a negative voltage lower than the word line write voltage VWLW. When the memory cell stores data 1 and the floating body voltage is FB “1”, if the word line is increased to the word line read voltage VWLR, the thyristor of the memory cell is brought in a conductive state, and a current flows through the bit line. However, when the floating body voltage is FB “0”, the thyristor of the memory cell is not brought in a conductive state, and the current does not flow through the bit line. Based on this difference, the data recorded in the memory cell can be read via the bit line. FIG. 4 in Non-Patent Document 1 discloses the same operation waveform diagram as that in FIG. 24.
Patent Document Japanese Patent Kokai Publication No. JP2009-176331A
Non-Patent Document 1: S. Slesazeck et al., “Vertical Capacitor-less Thyristor Cell for 30 nm Stand-alone DRAM”, 2009 Symposium on VLSI Technology Digest of Technical Papers P232-P233

### SUMMARY

### Discussion on the Related Art

The disclosure of the above Patent Document 1 and Non-patent Document 1 are incorporated herein in their entirety by reference thereto. The following analyses are given by the present disclosure.

According to either of the above Patent Document 1 or Non-Patent Document 1, information is recorded by storing a charge in the gate capacitor between the gate of the MOS transistor and the body node FB. In the above memory cell storing a charge in a floating body, the MOS transistor serves as a trigger element of the thyristor or the bipolar transistor. However, use of such MOS transistor causes the following problems.

As disclosed in Non-Patent Document 1, a GIDL (Gate Induced Drain Leakage) current is present in the MOS transistor. Particularly, when the memory cell is not selected, a large negative voltage needs to be applied to the gate controlling the floating body. As a result, the GIDL current is increased. This leakage current deteriorates refresh characteristics in a data retention period. It is generally assumed that the GIDL is the biggest factor among those causing a leakage current.

In addition, since ion implantation conditions need to be determined so that characteristics such as the Vt value of the MOS transistor are suitable, the leakage cu ent of each PN junction cannot be adjusted to a profile in which the junction leakage is minimized. In addition, when a MOS transistor is used in a memory cell, to prevent an area increase, a thyristor or a bipolar transistor can be vertically arranged in a column or wall region on a semiconductor substrate, and a gate (word line) can be arranged on a side wall of the thyristor or the bipolar transistor, as disclosed in Non-Patent Document 1. However, since it is difficult to process the word line, miniaturization will also be difficult.

Therefore, while it is not preferable to include a MOS transistor in either of the memory cells having floating bodies disclosed in Patent Document 1 and Non-Patent Document 1, it has been considered that lack of such MOS transistor as a trigger element makes it difficult to accurately control conductive and non-conductive states of the memory cell.

According to a first aspect of the present disclosure, there is provided a semiconductor device comprising a bit line, a memory cell, and a control circuit. The memory cell includes a switch circuit coupled to the bit line and a memory element configured to store either one of first and second data. The control circuit controls a voltage of the bit line to turn on the switch element in a first time period and to turn off the switch element in a second time period following the first time period when the control circuit writes the first data to the memory element. The control circuit controls the voltage of the bit line to turn on the switch element in the first time period and to maintain an on-state of the switch circuit in the second time period when the control circuit writes the second data to the memory element.

According to a second aspect of the present disclosure, there is provided a semiconductor device, comprising: a bit line; a word line; and a memory cell having a first terminal connected to the bit line and a second terminal connected to the word line; wherein, when data is written in the memory cell, irrespective of whether the write data represents first or second data, the memory cell is brought in a conductive state in a first period by setting the bit line to a first voltage level.

### BRIEF DESCRIPTION OF THE DRAWINGS

FIG. 1 is a circuit diagram of a sense amplifier and peripheral circuits thereof according to a first exemplary embodiment of the present disclosure.

FIG. 2 is a block diagram illustrating an overall configuration of a semiconductor device according to the first exemplary embodiment.

FIG. 3 is a circuit arrangement diagram of a memory cell region and peripheral regions thereof according to the first exemplary embodiment.

FIG. 4A is a circuit diagram of a memory cell (thyristor memory) according to the first exemplary embodiment and FIG. 4B illustrates a simplified circuit diagram symbol of the memory cell.

FIG. 5 is a graph illustrating characteristics of a general diode between a memory cell floating body and VSS.

FIG. 6 is a plan view of the memory cell region according to the first exemplary embodiment.

FIG. 7 is a sectional view of the memory cell region taken along line A-A according to the first exemplary embodiment.

FIG. 8 is a waveform diagram illustrating an operation of writing data in the memory cell according to the first exemplary embodiment.

FIG. 9 is a waveform diagram illustrating an operation of reading data from the memory cell according to the first exemplary embodiment.

FIG. 10 is a circuit diagram of a memory cell (FBC memory) according to a second exemplary embodiment.

FIG. 11 is a sectional view of a memory cell region taken along line A-A according to the second exemplary embodiment.

FIG. 12 is a block diagram illustrating an overall configuration of a semiconductor device according to a third exemplary embodiment.

FIG. 13 is a waveform diagram illustrating an operation of writing data in a memory cell according to the third exemplary embodiment.

FIG. 14 is a waveform diagram illustrating an operation of accessing a memory cell when an operation compatible with DRAM specifications is executed according to a fourth exemplary embodiment.

FIG. 15 is a waveform diagram illustrating a refresh operation with a memory cell according to a fifth exemplary embodiment.

FIG. 16 is a block diagram illustrating an overall configuration of a semiconductor device according to a sixth exemplary embodiment.

FIG. 17 is a circuit diagram of a sense amplifier and peripheral circuits thereof according to the sixth exemplary embodiment.

FIG. 18 illustrates voltage-to-current characteristics when a thyristor is in a conductive state according to the sixth exemplary embodiment.

FIG. 19 is a waveform diagram illustrating an operation of writing data in a memory cell according to the sixth exemplary embodiment.

FIG. 20 is a waveform diagram illustrating an operation of reading data from the memory cell according to the sixth exemplary embodiment.

FIG. 21 is a waveform diagram illustrating an operation of accessing a memory cell when an operation compatible with DRAM specifications is executed according to a seventh exemplary embodiment.

FIG. 22 is a waveform diagram illustrating a refresh operation with a memory cell according to an eighth exemplary embodiment.

FIGS. 23A and 23B are circuit diagrams for explaining a conventional thyristor and FBC memory cells, respectively.

FIG. 24 is an operation waveform diagram for explaining a conventional thyristor memory cell.

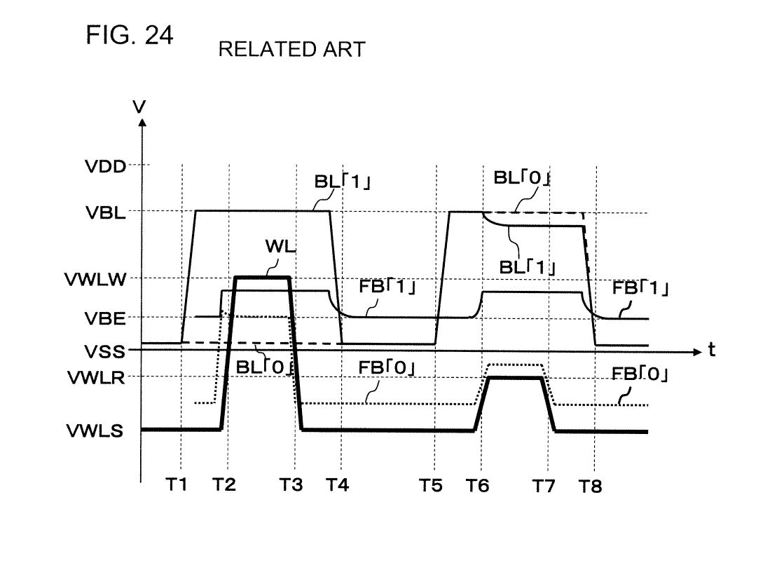

FIG. 25 is a waveform diagram illustrating an operation of writing data in a memory cell according to an undisclosed related technique.

### PREFERRED MODES

### Exemplary Embodiments

Before exemplary embodiments of the present disclosure will be described in detail, an outline of an exemplary embodiment of the present disclosure will be described. The drawings and the reference characters referred to in the following outline are merely used as examples to facilitate understanding of the present disclosure. Namely, the drawings and the reference characters are not intended to limit the present disclosure to the modes illustrated in the drawings.

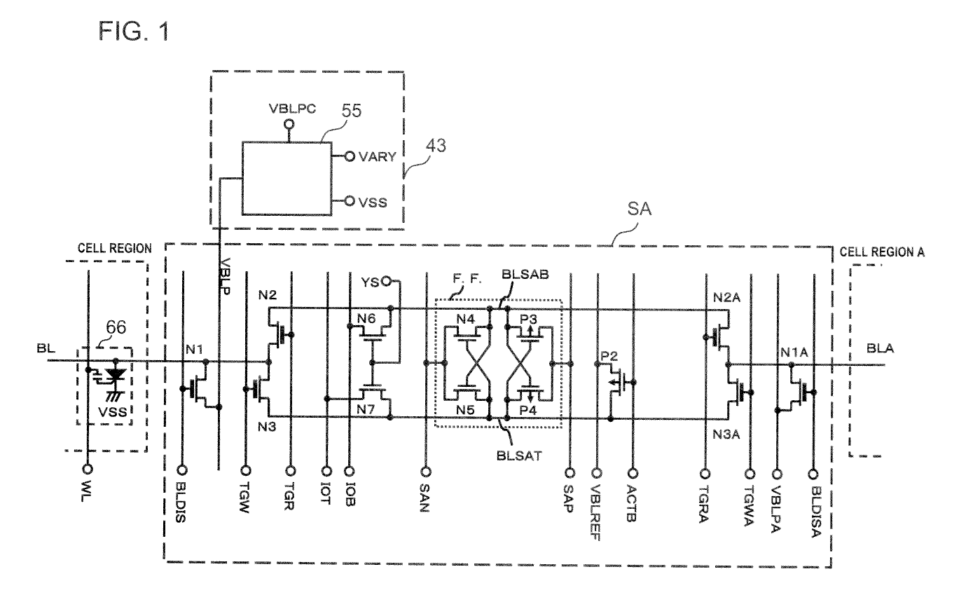

For example, as illustrated in FIGS. 1 to 4, FIG. 8, and FIG. 10, a semiconductor device (30) according to an exemplary embodiment of the present disclosure includes a bit line (BL), a word line (WL), and a memory cell (66, 66A). The memory cell has a first terminal connected to the bit line and a second terminal connected to the word line. The semiconductor device further includes a control circuit (42, 43). When data is written in the memory cell, the control circuit selects the bit line and the word line, and brings the memory cell in a conductive state irrespective of the level of the write data. Then the control circuit sets the bit line to a voltage level based on the write data to write the data in the memory cell.

According to the exemplary embodiment, when data is written in a memory cell, the memory cell is brought in a conductive state each time. Thus, since the charge amount that has been held by the floating body before writing is reset, a voltage level based on new write data can be recorded in the floating body.

In the present description, unless the context requires otherwise, “cell High” and “cell Low” indicate memory cells storing high- and low-level data, respectively.

In addition, in the present description, “cell High write waveform” and “cell Low write waveform” indicate waveforms of writing high- and low-level data in memory cells, respectively.

In addition, in the present description, “cell High read waveform” and “cell Low read waveform” indicate waveforms of reading high- and low-level data from memory cells, respectively.

In addition, in the present description, BL “H” indicates a bit line BL through which high-level data is written in or read from a memory cell.

In addition, in the present description, BL “L” indicates a bit line BL through which low-level data is written in or read from a memory cell.

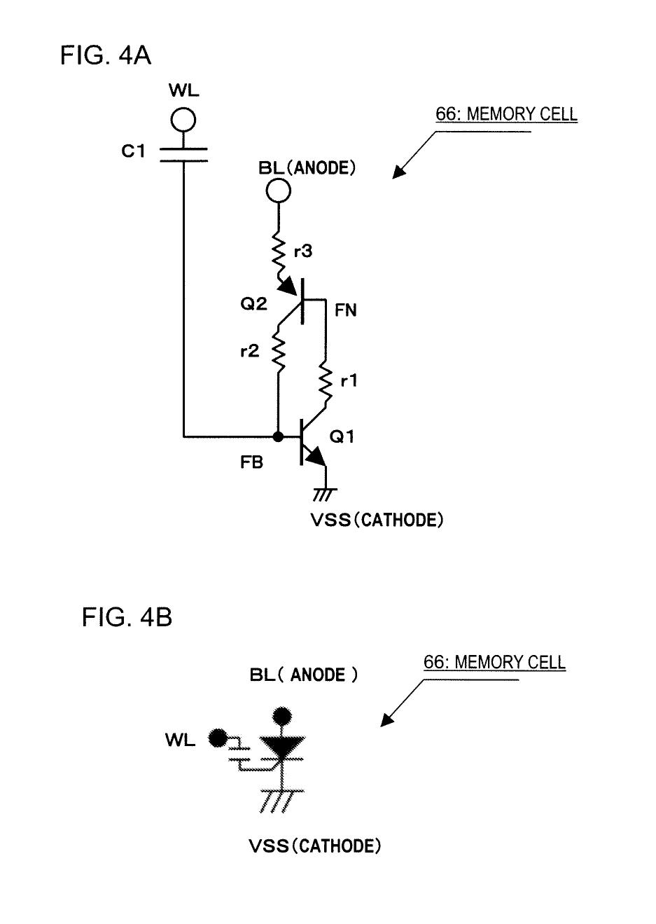

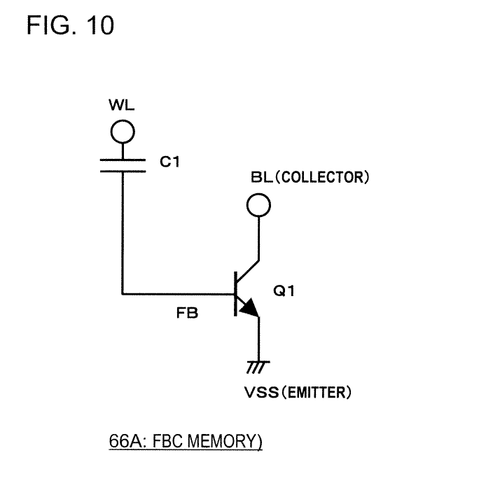

In addition, in the present description, FB “H” and FB “L” indicate a floating body FB (FB node) when a memory cell stores high- and low-level data, respectively. FIG. 4A illustrates an FB node when the memory cell is a thyristor memory, and FIG. 10 illustrates an FB node when the memory cell is an FBC memory.

Next, more specific exemplary embodiments will be described in detail with reference to the drawings.

### First Exemplary Embodiment

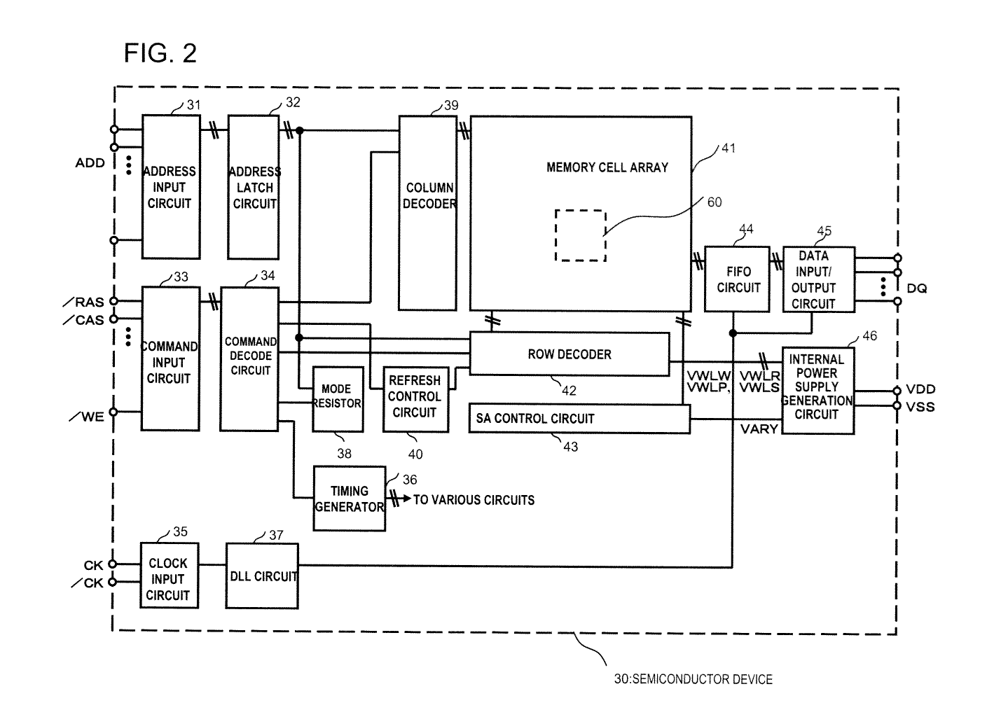

FIG. 2 is a block diagram illustrating an overall configuration of a semiconductor device 30 according to a first exemplary embodiment. The semiconductor device 30 according to the first exemplary embodiment includes a memory cell array 41 and can read and write data from and in the memory cell array 41 via data input/output terminals DQ, based on command signals (/RAS, /CAS, /WE, etc.) and address signals ADD supplied in synchronization with external clocks.

An address input circuit 31 receives addresses from address input terminals ADD. An address latch circuit 32 latches address signals supplied from the address input circuit 31 in synchronization with clocks. A command input circuit 33 receives command signals such as /RAS, /CAS, and /WE supplied from the outside. The slash mark in each of the signal names represents that the signal is set to be active when brought to a low level. A command decode circuit 34 decodes command signals supplied from the command input circuit 33 and controls operations of various units in the semiconductor device 30. A timing generator 36 generates operation timing signals for various circuits in the semiconductor device 30, based on results of decoding by the command decode circuit 34. A clock input circuit 35 receives clock signals CK and /CK from the outside. A DLL circuit 37 generates clock signals in synchronization with clocks supplied from the outside, so that data can be inputted/outputted at high speed in synchronization with the outside. A mode resistor 38 can be set by a command from the outside, and internal operations are controlled by values set in the mode resistor 38.

A column decoder 39 decodes a column address among the address signals and selects a bit line of a memory cell to be accessed among a plurality of bit lines (not illustrated in FIG. 2) in the memory cell array 41. A refresh control circuit 40 specifies a row address to be refreshed. In the memory cell array 41, a plurality of bit lines (not illustrated) that are selected by the column decoder 39 and a plurality of word lines (not illustrated) that are selected by a row decoder 42 cross each other. In addition, a plurality of memory cells (not illustrated) are arranged in a matrix, each of which corresponds to an intersection of a bit line and a word line. The internal configuration of the memory cell array 41 will be described in detail later. The row decoder 42 decodes a row address and selects a word line in the memory cell array 41. A sense amplifier (SA) control circuit 43 controls operations of sense amplifiers (not illustrated) included in the memory cell array 41.

When a read command is executed, a FIFO circuit 44 converts a plurality of bit data read in parallel from the memory cell array 41 into serial data and outputs the converted serial data to a data input/output circuit 45. When a write command is executed, the FIFO circuit 44 converts serial data inputted from DQ terminals via the data input/output circuit 45 into parallel data and outputs the converted parallel data to the memory cell array 41 as write data. The data input/output circuit 45 exchanges data with the FIFO circuit 44 and the DQ terminals used as external data input/output terminals. The DLL circuit 37 supplies a clock to the FIFO circuit 44 and the data input/output circuit 45, so that data can be inputted/outputted at high speed with an external device in synchronization with the clock. An internal power supply generation circuit 46 uses power supplies supplied via external power supply terminals VDD and VSS to generate power supplies necessary for internal operations. Main power supplies generated by the internal power supply generation circuit 46 includes: a power supply VARY that is supplied to the SA control circuit 43 and that is used for driving a bit line to a high level; and a word line write voltage VWLW, a word line read voltage VWLR, a word line precharge voltage VWLP, and a word line standby voltage VWLS that are supplied to the row decoder 42 and that are used as power supplies for driving word lines.

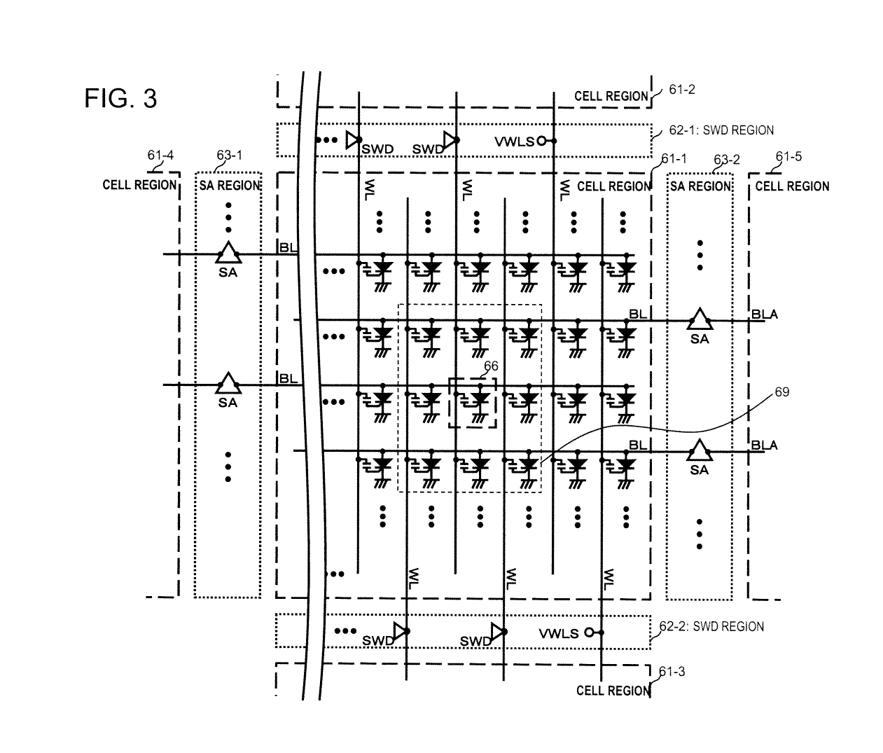

FIG. 3 is a circuit arrangement diagram of a memory cell region and peripheral regions thereof according to the first exemplary embodiment. FIG. 3 illustrates an internal circuit arrangement of a region 60 indicated by a dashed line in the memory cell array 41 in FIG. 2. Many cell regions 61 illustrated in FIG. 3 are arranged in a matrix in the memory cell array 41 in FIG. 2. Among the cell regions 61 arranged in a matrix. FIG. 3 illustrates a single cell region 61-1 and peripheral circuits thereof. SVVD regions 62-1 and 62-2 including sub-word drivers SWD are arranged above and below the cell region 61-1, respectively. In addition, (sub-) word lines WL alternately extend from the sub-word drivers SWD included in the SWD regions 62-1 and 62-2 to the cell region 61-1. Further, the word lines WL driven by the sub-word drivers SWD included in the SWD region 62-1 also extend to another cell region 61-2 adjacent to the cell region 61-1 via the SWD region 62-1. Likewise, the word lines WL driven by the sub-word drivers SWD included in the SWD region 62-2 also extend to the cell region 61-3.

SA regions 63-1 and 63-2 including sense amplifiers SA are arranged on the left and right sides of the cell region 61-1, respectively. Bit lines BL alternately extend from the sense amplifiers SA included in the SA regions 63-1 and 63-2 to the cell region 61-1. In addition, other bit lines extend from the sense amplifiers SA included in the SA region 63-1 to another cell region 61-4 adjacent to the cell region 61-1. Likewise, bit lines BLA extend from the sense amplifiers SA included in the SA region 63-2 to a cell region 61-5. A plurality of memory cells 66 are arranged in a matrix in the cell region 61-1, each memory cell 66 being arranged at an intersection of a bit line BL and a word line WL.

FIG. 4A illustrates an internal circuit of a single memory cell 66 in FIG. 3. In FIG. 4A, a thyristor is arranged between a bit line BL and a power supply node VSS, with an anode connected to the bit line BL and a cathode connected to the power supply node VSS. The thyristor includes: an NPN transistor Q1 having an emitter connected to the cathode, a base connected to a floating body FB, and a collector connected to a region FN via a parasitic resistance r1; and a PNP transistor Q2 having an emitter connected to the anode via a parasitic resistance r3, a base to the region FN, and a collector to the floating body FB via a parasitic resistance r2. In addition, a capacitor C1 is arranged between the floating body FB and a word line WL. FIG. 4B illustrates a simplified circuit diagram symbol of the memory cell 66 used in FIG. 1, FIG. 3, and the like. Namely, the memory cell 66 in FIGS. 4A and 4B includes a single thyristor and a single capacitor C1, but not a MOS transistor.

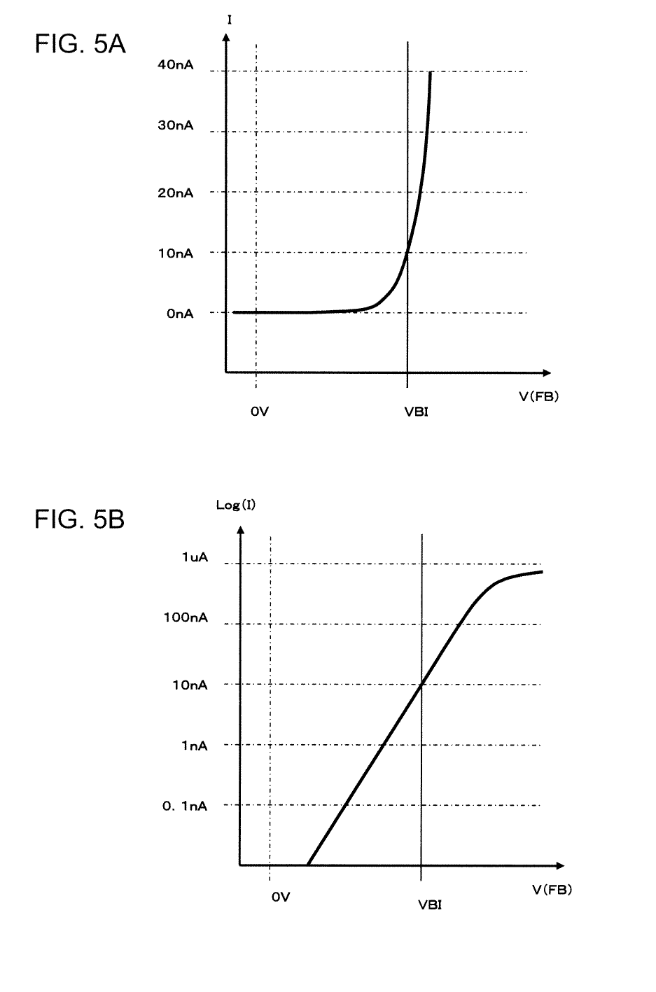

FIG. 5 is a graph illustrating forward characteristics of the PN diode between the floating body FB and the power supply VSS of the memory cell 66 (between the base and the emitter of the transistor Q1 in FIG. 4A). The horizontal axis in FIGS. 5A and 5B represents the voltage V(FB) of the floating body FB with respect to the power supply VSS. In FIG. 5A, current values are represented linearly along the vertical axis. In FIG. 5B, current values are exponentially represented along the vertical axis. As illustrated in FIGS. 5A and 5B, the current value flowing in the forward direction of the PN diode between the floating body FB and the power supply VSS is exponentially dependent on the voltage V(FB), namely, on the forward voltage. As illustrated in FIGS. 5A and 5B, a current of 10 nA flows when the forward voltage of the diode is a voltage VBI (built-in potential).

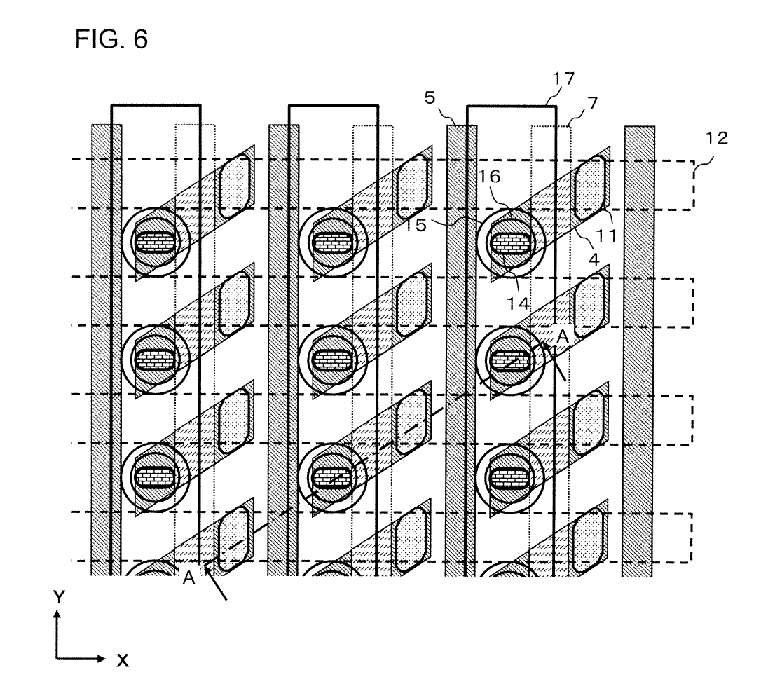

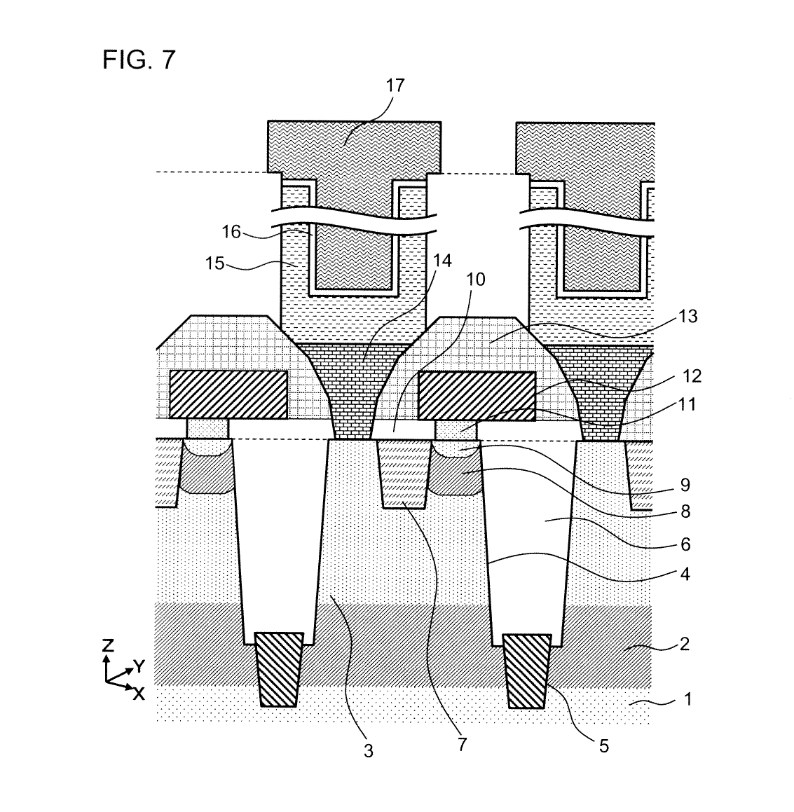

FIG. 6 is a plan view illustrating a memory cell region according to the first exemplary embodiment. More specifically, FIG. 6 is a plan view illustrating a region 69 indicated by a dashed line in FIG. 3. In addition, FIG. 7 illustrates a sectional view of the memory cell region, taken along line A-A in FIG. 6 and viewed from the arrow direction. In FIG. 7, an N-type cathode 2 and a P-body 3 of a diffusion layer 4 are stacked in this order on the front surface of a P-type semiconductor substrate 1. On a surface of the diffusion layer 4, an STI (shallow trench isolation) 6 is arranged in a wedge shape and extends into the N-type cathode 2. Each memory cell is divided from another memory cell by this STI 6. In addition, at the bottom of each STI 6, there is provided an embedded metal 5 in contact with the P-type semiconductor substrate 1 and the N-type cathode 2. Each N-type cathode 2 is electrically connected to an N-type cathode 2 adjacent thereto via the embedded metal 5 and serves as a power supply node common among the memory cells. From the middle of a surface of a P-body 3 arranged for each of the memory cells divided by the STIs 6, a recess 7 in a wedge shape extends into the diffusion layer 4. The surface of the P-body 3 of each memory cell is divided into two parts by the recess 7. In one of the surface parts, an N-type diffusion layer 8 and a P-type anode 9, which is a P-type diffusion layer, are stacked in this order.

An interlayer film 10 is arranged to cover the surface of the diffusion layer 4 including the P-type anode 9. A bit line contact 11 is arranged on the interlayer film 10 on the surface of the P-type anode 9, and the P-type anode 9 is connected to a bit line 12 that is arranged above the interlayer film 10 via the bit line contact 11. The sides and the top side of the bit line 12 are covered by a side wall 13, which is a nitride film. In addition, a capacitance contact 14 is arranged on the other surface part of the P-body 3, that is, on the surface opposite to the surface in which the N-type diffusion layer 8 and the P-type anode 9 are formed beyond the recess 7. The capacitance contact 14 runs through the interlayer film 10 and is connected to a lower electrode 15 of a capacitor arranged above the hit line 12. In addition, as a topmost wiring layer in the memory cell configuration, a word line 17 is arranged above the lower electrode 15 via a capacitance film 16.

This memory cell includes a thyristor. The thyristor includes the P-type anode 9, the N-type diffusion layer 8, the P-body 3, and the N-type cathode 2. The P-type anode 9 is connected to the bit line 12 via the bit line contact 11, and the N-type cathode 2 of the thyristor serves as a power supply node. In addition, the N-type cathode 2 and/or the embedded metal 5 are/is connected to an external power supply terminal VSS (not illustrated). In addition, the P-body 3 of the thyristor is connected to the word line 17 via the capacitance contact and the capacitor formed by the (lower) electrode 15, the capacitance film 16, and the word line 17. In addition, by arranging the recess 7, a region for the P-type anode 9 and the N-type diffusion layer 8 is assured in the P-body 3, and this region is separated from the region of the P-boy 3 connected to the capacitance contact 14.

As illustrated in FIGS. 6 and 7, the memory cell does not use any MOS transistor including parasitic transistor. Thus, the problems caused by using a MOS transistor in a memory cell, such as the GIDL current, are not caused. In addition, while the capacitor is electrically connected to the thyristor as a memory element via the capacitance contact 14, the capacitor and the thyristor as a memory element are arranged independently. Thus, even if impurity concentration or the like in each semiconductor region of such memory element is optimized, capacitor characteristics are not affected. In addition, a capacitor having necessary and sufficient capacitance can be arranged, without affecting memory element characteristics.

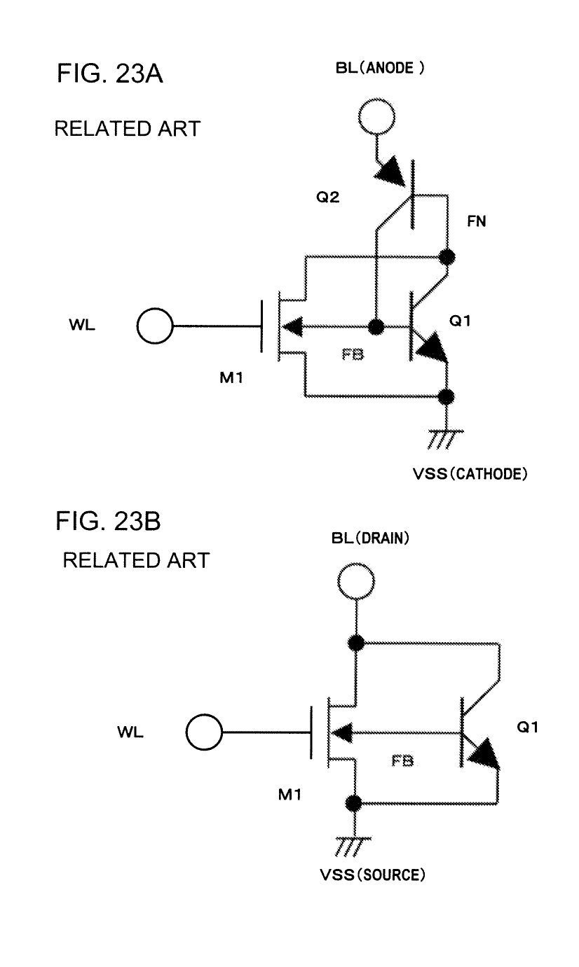

As disclosed in Non-Patent Document 1, in the case of the conventional thyristor memory in FIG. 23A in which the parasitic capacitance of the MOS transistor is used as the cell capacitance, the cell capacitance value between the body FB node (back bias of the NMOS transistor) and the gate is very small, approximately 10 aF (attofarad: 1E-18) to 50 aF in 30 nm process or less. If the process miniaturization is advanced in the future, the area between the body FB node and the gate will be further decreased, further decreasing the cell capacitance. As a result, a slight cell leakage current will deteriorate the refresh characteristics. The cell capacitance of a DRAM is approximately 25 fF (femtofarad: 1E-15), which is larger than the parasitic capacitance of this NMOS transistor by approximately 3 digits.

The charge of a carrier such as a hole or an electron is 0.16 aC (attocoulomb). Namely, for example, if the cell capacitance is 16 aF, leakage of a single carrier fluctuates the level of the body FB node by 10 mV. Assuming that a fluctuation of 0.5 V or greater with respect to the level of the body FB node after a write operation results in a read failure, a leakage of only 50 carriers causes a read failure or a refresh failure. The time during which carriers as few as 50 carriers leak is due to stochastic fluctuation and greatly varies every time. In the case of 50 carriers, 1σ (sigma: standard deviation) corresponds to a fluctuation of approximately 14%, and this value approximately matches the fluctuation of the leakage time. Probability of this fluctuation can be calculated accurately based on the Poisson distribution. Thus, reproducibility of the refresh operation is significantly deteriorated, making it difficult to execute redundancy recovery or selection of a refresh failure bit. To address this problem, the cell capacitance needs to be increased, so as to increase the number of leakage carriers that causes a refresh failure. The inventor has estimated through calculation that the number of the carriers needs to be at least about 1000. Namely, the cell capacitance needs to be approximately 0.32 fF (=0.16 aC×1000 carriers/0.5 V) or more.

In the device structure example in FIG. 7, while the capacitor is a concave-type capacitor (the electrode 15 is in the shape of a crown and has capacitance therein), the capacitor can be formed by the same process as that used to form a capacitor of a DRAM. There are various capacitor structures for a capacitor of a DRAM, and the present disclosure is applicable to any of the structures. Generally, in a DRAM, based on the product of the cell leakage current value and the necessary refresh characteristics, a capacitance of approximately 20 fF or more is needed. In recent years, it is becoming more difficult to assure such cell capacitance and achieve miniaturization. However, based on the semiconductor memory device of the present disclosure, the cell leakage current value can be improved significantly as described above. Thus, if refresh characteristics values are the same as those of a DRAM, the cell capacitance can be decreased. If the cell leakage current can be decreased by two digits or more from that of a DRAM, a cell capacitance of approximately 0.32 fF as described above can be allowed.

In addition, compared with that of a DRAM, the capacitance value of the capacitor can be decreased, in principle. Namely, when cell data is read, word and bit lines are selected and a thyristor (memory element) operates as an active element, to drive the bit line. Thus, compared with a DRAM reading memory cell capacitance via a switch (MOS transistor), the capacitance can be decreased in principle. In addition, it is only necessary that the memory element includes three PN junctions. In addition, unlike a MOS transistor, the memory element can be caused to serve as an active element without using a semiconductor substrate surface. Therefore, as illustrated in FIG. 7, by arranging the memory element vertically with respect to the semiconductor substrate, the cell area can be reduced easily.

### (Operation Principle of Thyristor Memory Cell)

An outline of the operation principle of a thyristor memory cell will be described with reference to the circuit diagram in FIG. 4A. If the voltage of the FB node is increased from a low voltage via the cell capacitor capacitance, more specifically, if the voltage between the FB node (P-type region) and the cathode VSS (N-type region) reaches a voltage close to a built-in potential VBI of the PN junction, a diode forward current starts to flow from the FB node to the cathode VSS. This current is equivalent to a current between the base and the emitter of the NPN bipolar transistor Q1.

When the voltage of the bit line BL (anode) is sufficiently high, if the voltage of the FB node is increased via the cell capacitor capacitance and the voltage is increased to a voltage close to the voltage VBI, the NPN bipolar transistor Q1 slightly turns on and a node FN is decreased to a low level. Consequently, the PNP bipolar transistor Q2 turns on, which increases the voltage of the FB node to a higher voltage. As a result, the NPN bipolar transistor Q1 turns on more strongly, and the anode BL and the cathode VSS of the thyristor memory cell are brought in a conductive state.

Once the thyristor memory cell is brought in a conductive state, as long as a sufficiently high voltage is applied to the bit line BL (anode), even if a coupling voltage is applied to the FB node via the cell capacitor capacitance, the thyristor memory cell maintains a conductive state.

The thyristor memory cell is brought in a non-conductive state by decreasing the potential difference between the anode BL and the cathode VSS to the voltage VBI or lower. If the voltage of the bit line BL is decreased to the voltage VBI or lower, because of the leakage current of the PN junction, the FB node is decreased to the voltage VBI or lower. As a result, since the NPN bipolar transistor Q1 turns off, the anode BL and the cathode VSS of the thyristor memory cell are brought in a non-conductive state.

When the voltage of the bit line BL (anode) is a sufficiently low voltage, e.g., the voltage VBI or lower, even if the voltage of the FB node is increased, the NPN bipolar transistor Q1 and the PNP bipolar transistor Q2 maintain an off-state. Thus, the anode BL and the cathode VSS of the thyristor memory cell does not always maintain a conductive state.

FIG. 1 is a circuit diagram of a sense amplifier SA and peripheral circuits thereof according to the first exemplary embodiment. The sense amplifier SA is connected to a bit line BL extending from a cell region and is also connected to a bit line BLA from another cell region A adjacent to the sense amplifier SA. An N-type transistor N1 has one of a source and a drain connected to the bit line BL, and the other one of the source and the drain is connected to a bit line drive power supply signal VBLP. In addition, the N-type transistor N1 has a gate connected to a bit line drive control signal BLDIS. The bit line drive power supply signal VBLP is a power supply signal outputted from a bit line drive power supply circuit 55 included in the SA control circuit 43 (see FIG. 2). Based on a control signal VBLPC outputted from the timing generator 36, the bit line drive power supply circuit 55 outputs the power supply VARY or VSS as the bit line drive power supply signal VBLP. In addition, as with the case of the N-type transistor N1, an N-type transistor N1A is connected to the bit line BLA. The N-type transistors N1 and NIA maintain the voltages of the bit lines BL and BLA, respectively, at the power supply VARY or VSS, irrespective of the data held by the sense amplifier SA.

An N-type transistor N2 has one of a source and a drain connected to the bit line BL and the other one of the source and the drain connected to an inverting sense amplifier bit line BLSAB. The N-type transistor N2 has a gate connected to a control signal TGR. The control signal TGR is activated and brought to a high level when data of the bit line BL is read. When a reading operation is executed, the bit line BL is connected to the inverting sense amplifier bit line BLSAB via the N-type transistor N2. Similarly, an N-type transistor N2A is arranged between the bit line BLA and the inverting sense amplifier bit line BLSAB, and the N-type transistor N2A has a gate connected to a control signal TGRA.

In addition, an N-type transistor N3 has one of a source and a drain connected to the bit line BL, the other one of the source and the drain connected to a non-inverting sense amplifier bit line BLSAT, and a gate connected to a control signal TGW. The control signal TGW is activated and brought to a high level when the bit line BL is driven based on data of the sense amplifier SA during a write operation. When a write operation is executed, the bit line BL is connected to the non-inverting sense amplifier bit line BLSAT via the N-type transistor N3. Similarly, an N-type transistor N3A is arranged between the bit line BLA and the non-inverting sense amplifier bit line BLSAT, and the N-type transistor N3A has a gate connected to a control signal TGWA.

A flip flop F.F. is arranged between the inverting sense amplifier bit line BLSAB and the non-inverting sense amplifier bit line BLSAT to amplify the electric potential difference between the inverting sense amplifier bit line BLSAB and the non-inverting sense amplifier bit line BLSAT. The flip flop F.F. includes P-type transistors P3 and P4 and N-type transistors N4 and N5. In addition, the flip flop F.F. is connected to power supplies SAP and SAN for the P- and N-type transistors, respectively. These power supplies SAP and SAN are activated only when the flip flop F.F. needs to operate. When activated, the power supplies SAP and SAN are set to the same potentials as the power supplies VARY and VSS, respectively. The maximum amplitude of the bit line BL is determined based on the voltages of these power supplies SAP, SAN, and VARY. When inactivated, the power supplies SAP and SAN are set to the same potentials as the power supplies VSS and VARY, respectively.

An N-type transistor N6 serves as a switch for connecting the inverting sense amplifier bit line BLSAB and an inverting IO line IOB, and an N-type transistor N7 serves as a switch for connecting the non-inverting sense amplifier bit line BLSAT and a non-inverting IO line IOT. These N-type transistors N6 and N7 are controlled to be in a conductive/non-conductive state by a column selection signal YS. When read and write data is transmitted to and from the outside of the memory cell array, the inverting sense amplifier bit line BLSAB is connected to the inverting IO line IOB and the non-inverting sense amplifier bit line BLSAT is connected to the non-inverting IO line IOT via these N-type transistors N6 and N7.

A P-type transistor P2 is connected between the non-inverting sense amplifier bit line BLSAT and a bit line determination reference power supply VBLREF. The P-type transistor P2 has a gate connected to a control signal ACTB. The control signal ACTB is activated and brought to a low level when a read operation is executed.

Thick-film transistors having higher withstanding voltages are used as the N-type transistors N1 to N3 and NIA to N3A, compared with the surrounding other transistors. Preferably, NMOS and PMOS transistors can be used as the N-type and P-type transistors, respectively.

### (Writing Data in Memory Cell According to First Exemplary Embodiment)

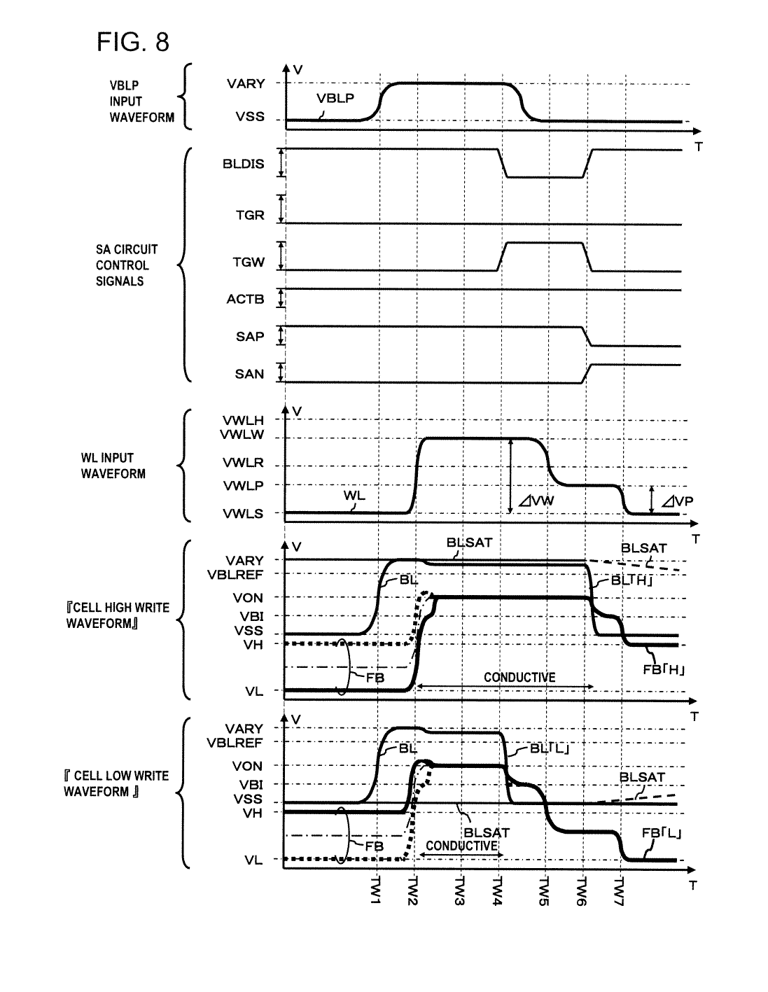

Next, an operation according to the first exemplary embodiment will be described. FIG. 8 is a waveform diagram illustrating an operation of writing data in a memory cell according to the first exemplary embodiment. An operation of writing data in the memory cell 66 will be described with reference to FIGS. 1 and 8.

In FIG. 8, before timing TW1, the memory cell 66 is in a standby state, namely, both the bit line BL and the word line WL are in a non-selected state. In this state, the bit line drive power supply signal VBLP is fixed at the VSS level, the bit line drive control signal BLDIS is fixed at a high level, and both the control signals TGR and TGW are fixed at a low level. Namely, since separated from the non-inverting sense amplifier bit line BLSAT and the inverting sense amplifier bit line BLSAB of the sense amplifier SA, the bit line BL is fixed at a low level (VSS). In addition, the power supply SAP used for the P-type transistors of the flip flop F.F. of the sense amplifier SA is supplied with the voltage VARY, and the power supply SAN used for the N-type transistors is supplied with the voltage VSS. Since the flip flop F.F. is activated, the control signal ACTB is fixed at a high level, which corresponds to an inactive level. In this state, the flip flop F.F. holds write data previously inputted from the IO lines IOT and JOB. Thus, if write data is at a high level, the voltage of the non-inverting sense amplifier bit line BLSAT is the same as the voltage VARY, and if write data is at a low level, the voltage is the same as the voltage VSS.

In addition, the word line WL is fixed at the word line standby voltage VWLS, which corresponds to a non-selected state. During this period, the FB node (see FIG. 4A) of the memory element (thyristor) (corresponds to the P-body 3 in FIG. 7) is at a potential VH or VL, depending on the logic level of the data held by the memory cell. The potential VH is higher than the potential VL and is lower than the voltage VBI.

At timing TW1, the bit line drive power supply circuit 55 increases the bit line drive power supply signal VBLP from the voltage VSS to the voltage VARY. Since the bit line drive control signal BLDIS is maintained at a high level, the voltage of the bit line BL is also increased from the voltage VSS to the voltage VARY. At this timing, even if the voltage of the bit line BL is increased to the high level VARY, since the voltage of the word line WL is maintained at the standby voltage VWLS, the voltage of the FB node does not change from the voltage that has been applied before timing TW1. Thus, the memory element does not operate.

At the next timing TW2, a sub-word driver SWD increases the voltage of the word line WL to the word line write voltage VWLW. Accordingly, if the data that has been held by the memory cell is at the high level VH, the voltage of the FB node is increased to the voltage VBI or greater via the cell capacitor capacitance. If the data is at the low level VL, the voltage is increased close to the voltage VBI.

Irrespective of the write data held by the flip flop F.F. of the sense amplifier SA, since the bit line BL is driven to the high level (VARY), the thyristor is brought in a conductive state. When the thyristor is brought in a conductive state, the voltage of the bit line BL is slightly decreased by on-resistance of the N-type transistor N1 and resistance of the bit line BL. In addition, the FB node (see FIG. 4A) of the memory cell 66 is brought to a voltage level VON determined by on-resistance of the PNP bipolar transistor Q2, characteristics of the pn junction diode (see FIG. 5) between the FB node and the power supply VSS (cathode), and the ratio among the parasitic resistances r1 to r3, for example.

At timing TW4, the bit line drive control signal BLDIS is decreased from a high level to a low level, and the control signal TGW is increased from a low level to a high level. Consequently, the bit line BL is connected to the non-inverting sense amplifier bit line BLSAT, and the bit line voltage BL “H” used for writing a high level in the memory cell 66 is continuously supplied with the voltage VARY. As a result, the thyristor of the memory cell 66 maintains a conductive state. However, the bit line voltage BL “L” used for writing a low level in the memory cell is started to be supplied with the voltage VSS. Thus, the thyristor of the memory cell 66 is brought in a non-conductive state, and the voltage FB “L” of the FB node of the memory cell is rapidly decreased to the voltage VBI because of the PN junction between the FB node (P-type region) and the cathode VSS (N-type region).

After timing TW4, the voltage level of the bit line drive power supply signal VBLP is decreased to the voltage VSS by timing TW6, at which the bit line drive control signal BLDIS is increased to a high level, again.

At timing TW5, the sub-word line driver SWD decreases the voltage of the bit line to the word line precharge voltage VWLP that is an intermediate voltage between the word line write voltage VWLW and the word line standby voltage VWLS. When a high level is written in the memory cell, since the bit line maintains a high level (VARY), the memory element thyristor is still in a conductive state. Thus, while the voltage of the word line WL is decreased to the word line precharge voltage VWLP, the voltage of the FB node is maintained at the voltage VON.

On the other hand, if low-level data is written in the memory cell, the voltage of the bit line BL is decreased to the voltage VSS at timing TW4. Namely, since the thyristor is already brought in a non-conductive state, the voltage of the FB node is decreased to a voltage further lower than the voltage VBI via the cell capacitor capacitance, along with the decrease of the voltage of the word line WL.

At timing TW6, the control signal TGW is decreased, the bit line BL is disconnected from the non-inverting sense amplifier bit line BLSAT, and the bit line drive control signal BLDIS is increased. Consequently, the voltage of the bit line BL is fixed at the voltage VSS corresponding to the bit line drive power supply signal VBLP. In addition, the power supplies SAP and SAN of the flip flop F.F. of the sense amplifier SA are changed to the low and high levels, respectively, to inactivate the flip flop F.F. Therefore, after timing TW6, the non-inverting sense amplifier bit line BLSAT is maintained in a floating state.

If high-level data is written in the memory cell, as the voltage of the bit line BL is decreased to the voltage VSS, the memory element thyristor is brought to a non-conductive state, and the voltage level of the FB node is rapidly decreased to the voltage VBI. On the other hand, when low-level data is written in the memory cell, since the voltage of the bit line BL is maintained at a low level (VSS), the state of the memory cell does not change.

At timing TW7, the voltage of the word line WL is decreased from the word line precharge voltage VWLP to the word line standby voltage VWLS. Since the memory element thyristor is in a non-conductive state, the voltage of the FB node is also decreased via the cell capacitor capacitance. If high-level data is written in the memory cell, the voltage of the FB node is decreased to the voltage VH. If low-level data is written, the voltage of the FB node is further decreased to the voltage VL. The electric potential difference between these VH and VL is held by the FB node as the data that has been written in the memory cell.

As can be understood from the above description, when a write operation executed, the memory element is brought in a non-conductive state, as the voltage of the bit line BL is decreased toward the voltage VSS. Next, the FB node is influenced by coupling of the voltage change amount of the word line WL via the cell capacitor capacitance. Thus, the voltage of the FB node after a write operation can be represented by the following Expression 1 or 2. Expressions 1 and 2 represent the voltages of the FB node after high- and low-level data is written, respectively.

VH=VBI−ΔVP (Expression 1)

VL=VBI−ΔVW (Expression 2)

ΔVP is the potential difference between the word line precharge voltage VWLP and the word line standby voltage VWLS, and ΔVW is the potential difference between the word line write voltage VWLW and the word line standby voltage VWLS.

Strictly, there are cases where the FB node level after a write operation slightly differs from Expression 1 or 2, depending on settings of the write timings. For example, if a short period is set between timing TW4 and timing TW5 and if a low level is written in the memory cell, the potential of the FB “L” can be set to the VL level almost exactly. However, if a long period is set between timing TW4 and timing TW5, the FB “L” level immediately before timing TW5 is decreased lower than the voltage VBI, based on the characteristics illustrated in FIG. 5. Thus, the FB “L” level after a write operation is decreased lower than Expression 2. In the present specification, VH and VL levels are defined as the values obtained by Expression 1 and Expression 2, respectively.

In addition, the built-in potential voltage VBI is dependent on the temperature. More specifically, the voltage VBI is higher at a lower temperature and lower at a higher temperature. Accordingly, the voltages VH and VL are also higher at a lower temperature and lower at a higher temperature.

(Reading Data from Memory Cell)

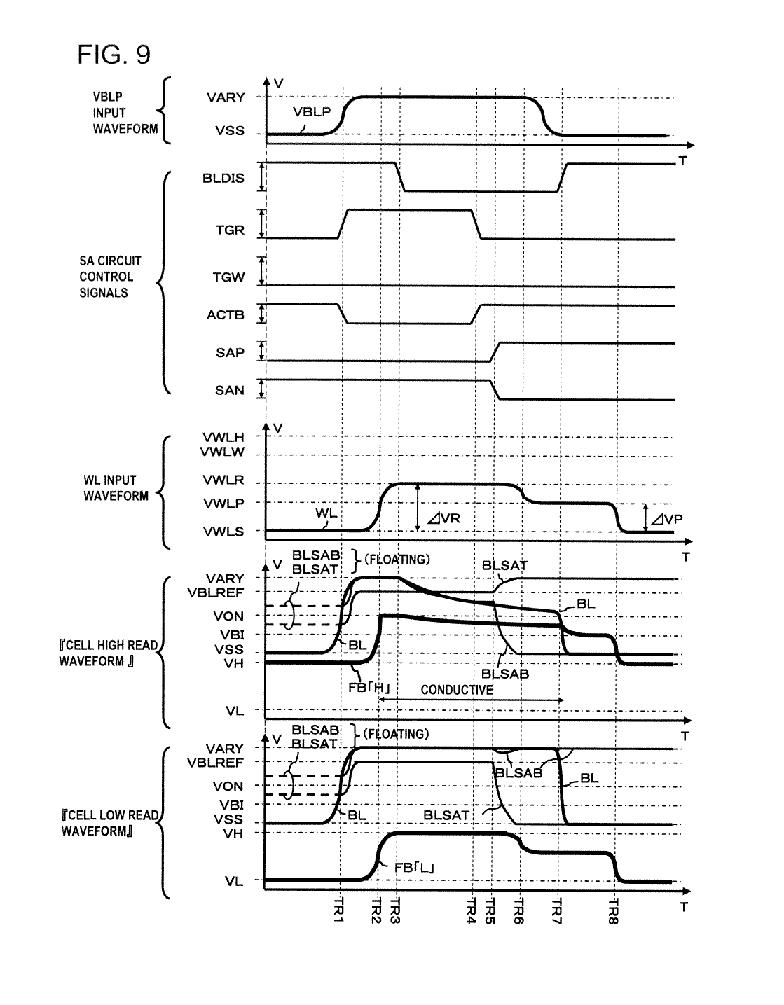

FIG. 9 is a waveform diagram illustrating an operation of reading data from a memory cell according to the first exemplary embodiment. An operation of reading data from a memory cell will be described with reference to FIGS. 1 and 9. Before timing TR1, the memory cell is in a standby state, namely, both the bit line BL and the word line WL are in a non-selected state. In this state, the bit line drive power supply signal VBLP is fixed at the VSS level, the bit line drive control signal BLDIS is fixed at a high level, and both the control signals TGR and TGW are fixed at a low level. Namely, since disconnected from the non-inverting sense amplifier bit line BLSAT and the inverting sense amplifier bit line BLSAB of the sense amplifier SA, the bit line BL is fixed at a low level (VSS) by the transistor N1. In addition, the power supplies SAP and SAN used for the P- and N-type transistors of the flip flop F.F. of the sense amplifier SA are at low and high levels, respectively. The flip flop F.F. is in an inactive state, and both the non-inverting sense amplifier bit line BLSAT and the inverting sense amplifier bit line BLSAB are in a floating state. The control signal ACTB is also at a high level, that is, in an inactive level. In addition, the FB node of the memory cell is at the voltage VH or VL, depending on the data held by the memory cell.

At timing TR1, the bit line drive power supply circuit 55 increases the bit line drive power supply signal VBLP from the voltage VSS to the voltage VARY. Since the bit line drive control signal BLDIS is maintained at a high level, the bit line BL is increased from the voltage VSS to the voltage VARY by the voltage outputted from the bit line drive power supply signal VBLP. Simultaneously, since the control signal TGR is increased to a high level and is then activated, the inverting sense amplifier bit line BLSAB is connected to the bit line BL. Consequently, the voltage of the inverting sense amplifier bit line BLSAB is increased to the voltage VARY. In addition, since the control signal ACTB is decreased to a low level and is then activated, the voltage of the non-inverting sense amplifier bit line BLSAT is changed to the hit line reference voltage VBLREF.

At timing TR2, the sub-word driver SWD increases the voltage of the word line WL to the word line read voltage VWLR. The word line read voltage VWLR is lower than the word line write voltage VWLW but higher than the word line precharge voltage VWLP. Since the voltage of the word line WL is increased to the word line read voltage VWLR at timing TR2, the voltage of the FB node is also increased via the capacitor capacitance of the memory cell. If the memory cell holds a high level and the voltage of the FB node is at the VH level, the increase of the word line WL increases the voltage of the FB node to the voltage VBI at which the memory element (thyristor) is brought in a conductive state. In this way, the memory element is brought in a conductive state. If the memory cell holds a low level and the voltage of the FB node is at the VL level, the increase of the word line WL also increases the voltage of the FB node. However, the voltage of the FB node is not increased to as high as the voltage VBI at which the memory element (thyristor) is brought in a conductive state. Namely, the memory element is not brought in a conductive state.

At timing TR3, the bit line drive control signal BLDIS is decreased to a low level, and the bit line BL is released from the voltage VARY. Since the inverting sense amplifier bit line BLSAB is connected to the bit line BL via the N-type transistor N2, if the memory element (thyristor) of the memory cell has been in a conductive state, the voltages of the bit line BL and the inverting sense amplifier bit line BLSAB are gradually decreased. If the memory element (thyristor) has not been in a conductive state, since there is no current flow route, the voltages of the bit line BL and the inverting sense amplifier bit line BLSAB are maintained at the voltage VARY. The voltage of the non-inverting sense amplifier bit line BLSAT is maintained at the bit line reference voltage VBLREF via the P-type transistor P2. In addition, after timing TR3, the voltage level of the bit line drive power supply signal VBLP is decreased from the voltage VARY to the voltage VSS by timing TR7, at which the bit line drive control signal BLDIS is increased to a high level, again.

At timing TR4, the control signal TGR is decreased to a low level, to disconnect the bit line BL from the inverting sense amplifier bit line BLSAB. Simultaneously, the read control signal ACTB is increased to a high level, to disconnect the voltage of the non-inverting sense amplifier bit line BLSAT from the bit line reference voltage VBLREF.

Next, at timing TR5, the power supplies SAP and SAN used for the p-type and N-type transistors of the flip flop F.F. of the sense amplifier SA are set to high (VARY) and low (VSS) levels, respectively, to activate the flip flop F.F. Consequently, the flip flop F.F. starts to amplify the electric potential difference between the non-inverting sense amplifier bit line BLSAT and the inverting sense amplifier bit line BLSAB. When the memory cell holds a high level and the memory element has become conductive due to the rise of the word line WL, the non-inverting sense amplifier bit line BLSAT and the inverting sense amplifier bit line BLSAB are amplified to a high level and low level, respectively, since the voltage of the inverting sense amplifier bit line BLSAB has dropped to a voltage not greater than the reference voltage VBLREF. Conversely, when the memory cell holds a low level and the memory element is not made conductive by the rise of the word line, the non-inverting sense amplifier bit line BLSAT and the inverting sense amplifier bit line BLSAB are amplified to a low level and high level, respectively, since the voltage of the inverting sense amplifier bit line BLSAB continues to be the voltage VARY.

At timing TR6, the sub-word driver SWD decreases the voltage of the word line WL from the word line read voltage VWLR to the word line precharge voltage VWLP. If the memory cell holds a high level, the voltage of the bit line BL is gradually decreased. However, since the memory element (thyristor) is still in a conductive state at this timing, the PNP transistor Q2 (see FIG. 4A) is still on. Thus, the voltage of the FB node is maintained at a voltage over the built-in potential voltage VBI. If the memory cell holds a low level, the memory element (thyristor) is not in a conductive state. Thus, as the voltage of the word line WL is decreased, the voltage of the FB node is also decreased via the capacitor capacitance of the memory cell.

At timing TR7, the bit line drive control signal BLDIS is increased, and the voltage of the bit line BL is fixed at a low level (VSS). If the memory cell holds a high level, the memory element (thyristor) is brought in a non-conductive state, and the voltage level of the FB node is rapidly decreased to the voltage VBI. If the memory cell holds a low level, since the memory element is maintained in a non-conductive state, the voltage of the FB node does not change.

At timing TR8, the sub-word driver SWD decreases the voltage of the word line WL from the word line precharge voltage VWLP to the word line standby voltage VWLS. Since the memory element (thyristor) is in a non-conductive state, the voltage of the FB node is also decreased via the cell capacitor capacitance. If high-level data is written in the memory cell, the voltage of the FB node is decreased to the voltage obtained by Expression 1, namely, to the voltage VH. If low-level data is written in the memory cell, the voltage of the FB node is decreased to the voltage VL, which is the voltage of the FB node before timing TR1. Namely, even after a read operation is executed, the memory cell data before the read operation can be maintained.

### (Meritorious Effects of First Exemplary Embodiment)

Based on a semiconductor device according to the first exemplary embodiment, when data is written in a memory cell, the memory cell is always brought in a conductive state and a write operation based on the write data is executed, whether the write data represents a high level or a low level. Through this operation, the voltage level of the FB node after the write operation can be set to a stable voltage level based on the write data, irrespective of the logic level of the data held by the FB node prior to the write operation.

To describe meritorious effects according to the first exemplary embodiment in which a write operation based on write data is executed after the memory cell is brought in a conductive state irrespective of the write data, a reference example, which is a related technique examined prior to the disclosure of the present application by the present inventors, will be described. This reference example has not been disclosed at least prior to filing of the present application.

In this reference example, a memory cell having the same structure as that illustrated in FIGS. 6 and 7 according to the first exemplary embodiment is used. In addition, peripheral circuit configurations similar to those according to the first exemplary embodiment are used. However, when data is written in a memory cell, the memory cell is not certainly brought in a conductive state irrespective of the write data before the data is written.

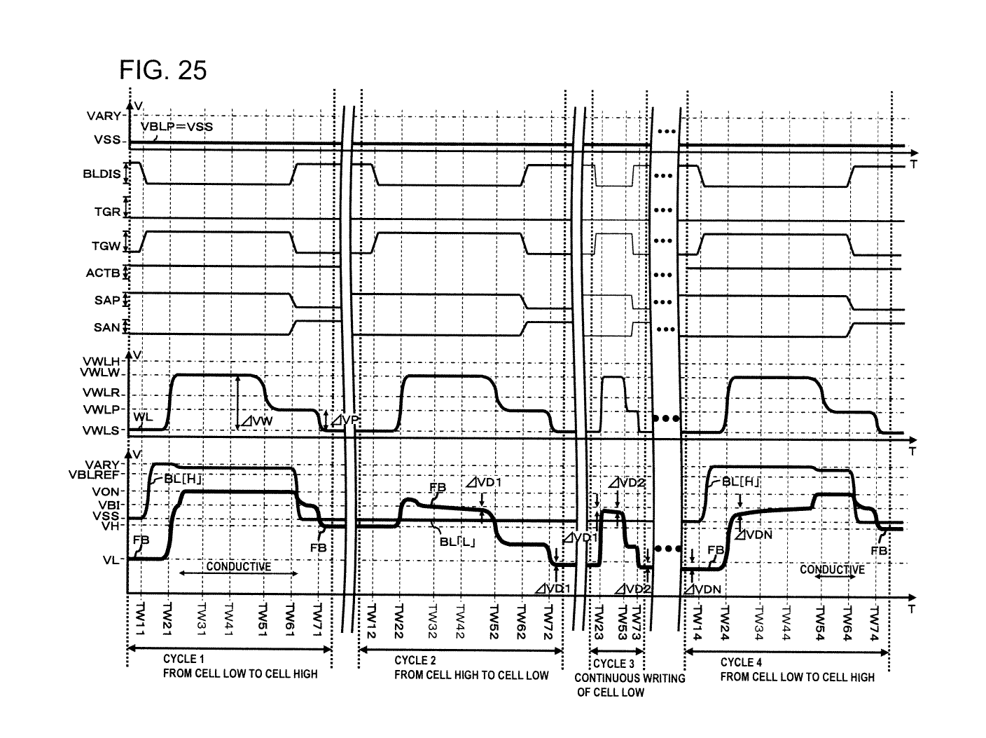

FIG. 25 is a waveform diagram illustrating a write operation of the reference example. In this reference example, as illustrated in FIG. 25, at the first timing TW11 of the write operation, the bit line drive control signal BLDIS is decreased to release the bit line BL that has been fixed at the voltage VSS. Simultaneously, the control signal TOW is increased, and the bit line BL is driven by write data held by the flip flop F.F. of the sense amplifier SA. Thus, if a high level is written in the memory cell, the voltage of the bit line BL is increased to the voltage VARY. However, if a low level is written in the memory cell, the voltage of the bit line BL is maintained at the voltage VSS.

Timing TW11 to Timing TW71 in FIG. 25 represent cycle 1 for writing a high level in a memory cell holding a low level. The potentials of the bit line BL, the word line WL, and the FB node are the same as those of the bit line BL, the word line WL, and the FB node in timing TW1 to timing TW7 in FIG. 8 illustrating an operation executed when a high level is written in a memory cell according to the first exemplary embodiment.

Next, from timing TW12 to timing TW72 in cycle 2 in FIG. 25, a low level is written in a memory cell holding a high level. If timing TW12 to timing TW72 is compared with the timing TW1 to timing TW7 used when a low level is written in a memory cell according to the first exemplary embodiment illustrated in FIG. 8, at timing TW12, a high level is not applied to the bit line BL, and the memory cell is not brought in a conductive state. The bit line BL is maintained at a low level during the write cycle period in cycle 2. In this case, when the voltage of the word line WL is increased to the voltage VWLW at tuning TW22, the voltage of the FB node reaches a voltage level exceeding the voltage VBI. However, because of the forward leakage current of the parasitic PN diode between the base and the emitter of the NPN transistor Q1 of the memory cell, the voltage level of the FB node is rapidly decreased to the voltage VBI. As described with FIGS. 5A and 5B, the current flowing through the diode is exponentially dependent on the forward bias voltage. Thus, if the forward bias voltage exceeds the VBI level, a large current flows rapidly. Namely, when the thyristor is in a non-conductive state, if the voltage of the FB node is over the voltage VBI, the voltage of the FB node is rapidly decreased close to the voltage VBI.

For example, in FIG. 4A, if the capacitance value of the capacitor C1 is 5 fF and the diode current is 10 nA, a voltage of 10 mV drops in 5 ns.

(10 nA×5 ns/5 fF=10 mV)

If the forward bias is the VBI level or lower, the current flowing through the parasitic PN diode is rapidly decreased to a small current value. However, since the current is not decreased to zero, if left alone for a long period of time when the thyristor is in a non-conductive state, the voltage of the FB node is gradually decreased to a level lower than the VBI level. If left alone for a very long period of time, the voltage of the FB node is decreased close to the VSS level.

In cycle 2 in FIG. 25, at timing TW22, the voltage level of the FB node is rapidly decreased to the voltage VBI. Thereafter, immediately before timing TW52, the voltage of the FB node is decreased lower than the VBI level by ΔVD1. Since the word line WL is decreased by a total of VW at timing TW52 and timing TW72, the level of the FB “L” after a low level is written is VBI−ΔVW−ΔVD1 (=VL−ΔVD1), to be exact.

In cycle 3, a low level is written in the memory cell, again. When the word line WL is increased from the word line standby voltage VWLS to the word line write voltage VWLW at timing TW23, the voltage of the FB node is increased to VBI−ΔVD1. In addition, between timing TW23 and timing TW53, the voltage of the FB node is further decreased. At timing TW53, the voltage is at VBL−ΔVD2. Thus, the level of the FB node immediately after cycle 3 is VL−ΔVD2 which is lower than the voltage immediately after cycle 2 (VL−ΔVD2<VL−ΔVD1).

If a low level is continuously written in the memory cell a plurality of times after cycle 3, the FB node level after such write operations is further decreased. Immediately before cycle 4, the voltage level of the FB node is as low as VL−ΔVDN (VL−ΔVDN<VL−ΔVD2).

In cycle 4, an operation of rewriting a memory cell holding a low level with a high level. At timing TW14, the bit line BL “H” is increased to VARY. Next, at timing TW24, the word line WL is increased from the word line standby voltage VWLS to the word line write voltage VWLW. Immediately after timing TW24, the voltage of the FB node is VBI−ΔVDN and on-performance of the NPN bipolar transistor Q1 is very low. Thus, a long period of time is required for the thyristor to be brought in a conductive state. In this example, the thyristor is brought in a conductive state immediately before timing TW54. At timing TW54, the word line WL is decreased from the word line write voltage VWLW to the word line precharge voltage VWLP. Since the thyristor is in a conductive state at this timing in this waveform example, the memory cell holding a low level can be rewritten with a high level.

However, if the thyristor has not been brought in a conductive state yet at timing TW54, a high level cannot be written in the memory cell, resulting in a failure.

Whether or not the thyristor is in a conductive state at timing TW54 is dependent on the ΔVDN level, namely, for example, on the number of consecutive cell Low rewrite cycles immediately before cycle 4 and on the amplification characteristics of the NPN bipolar transistor Q1. In any case, if the thyristor memory in FIG. 4A is used, if the word line WL and the bit line BL are controlled as illustrated in the cell write operation waveforms in FIG. 25, and if a low level is consecutively written in the memory cell, when a high level is next written in the memory cell, the margin for writing the high level will be small. This is an unsolved problem.

With the conventional thyristor memory and FBC memory having the NMOS transistor M1 as a trigger element as illustrated in FIGS. 23A and 23B, if the word line write voltage VWLW is set to be a voltage over VT of M1, when an operation of rewriting from cell Low to cell High in cycle 4 in FIG. 25 is executed, instead of the NPN bipolar transistor Q1, the NMOS transistor M1 can certainly be turned on at timing TW24. Thus, the above problem is not caused. The unsolved problem has been unique to cases where a memory cell does not use a trigger element as an active element (a memory cell that does not use a MOS transistor).

According to the first exemplary embodiment, irrespective of the write data, after the memory cell is brought in a conductive state, the voltage level of the bit line is set to be a voltage level based on the write data and writing is executed. In this way, even if a low level is written consecutively, the voltage level of the FB node after writing is not subjected to a voltage drop of ΔVD1 to ΔVDN. In addition, by setting the period between timing TW4 and TW5 to be an appropriately short period, the voltage level of the FB node after the cell low level write operation can almost exactly be set to a stable voltage level obtained by Expression 2. Therefore, the above problem can be solved.

### Second Exemplary Embodiment

The above first exemplary embodiment has been described assuming that the memory cell is a thyristor memory. The present disclosure is applicable to other types of memory cells such as an FBC memory, as long as the memory cell stores data in a floating body. In the second exemplary embodiment, an FBC memory is used as the memory cell. FIG. 10 is a circuit diagram illustrating a memory cell (FBC memory) according to the second exemplary embodiment. When the circuit diagram in FIG. 10 is compared with the circuit diagram in FIG. 4A illustrating the memory cell according to the first exemplary embodiment, it is seen that a bipolar transistor Q1 has a collector connected to the bit line BL, an emitter connected to the ground voltage VSS, and a base serving as the FB node and connected to one end of the capacitor C1. As in the first exemplary embodiment, the other end of the capacitor C1 is connected to the word line WL.

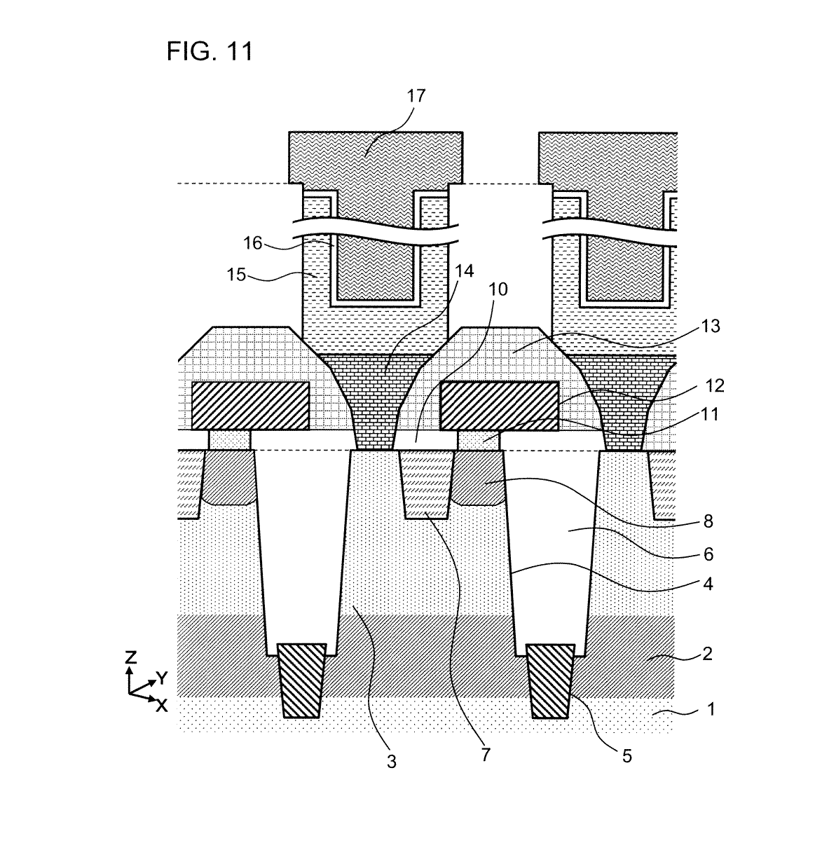

FIG. 11 is a sectional view of the memory cell according to the second exemplary embodiment. When FIG. 11 is compared with FIG. 7 illustrating a sectional view of the memory cell of the thyristor memory 66 according to the first exemplary embodiment, it is seen that only the difference between FIGS. 7 and 11 is that the P-type anode (P-type diffusion layer) 9 is not arranged between the N-type diffusion layer 8 and the bit line contact (P-type polysilicon) 11. Instead, the N-type diffusion layer 8 and the bit line contact (P-type polysilicon) 11 are directly connected to each other.

Since substantially the same circuit configurations and the same operation timings as those according to the first exemplary embodiment can be used for the memory cell peripheral circuits and operation timings according to the present exemplary embodiment, detailed descriptions thereof will be omitted. Thus, even when the memory cell is an FBC memory, the same advantageous effects as those obtained by the first exemplary embodiment can be obtained.

### Third Exemplary Embodiment

### Configuration of Third Exemplary Embodiment

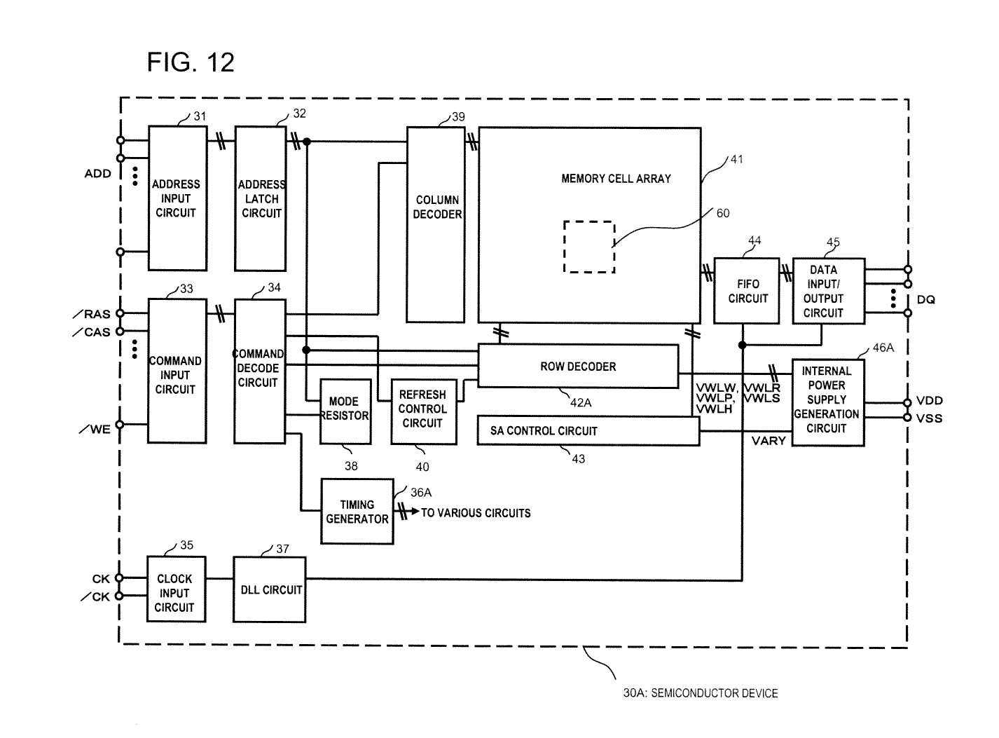

FIG. 12 is a block diagram illustrating an overall configuration of a semiconductor device 30A according to a third exemplary embodiment. In FIG. 12, configurations approximately the same as those illustrated in the block diagram of the semiconductor device 30 according to the first exemplary embodiment in FIG. 2 are denoted by the same reference characters, and repetitive descriptions will be omitted. In FIG. 12, in addition to the word line write voltage VWLW, the word line read voltage VWLR, the word line precharge voltage VWLP, and the word line standby voltage VWLS, an internal power supply generation circuit 46A supplies an word line overshoot voltage VWLH to a row decoder 42A. Further, in addition to the word line write voltage VWLW, the word line read voltage VWLR, the word line precharge voltage VWLP, and the word line standby voltage VWLS, the row decoder 42A uses the word line overshoot voltage VWLH to drive the word line WL.

A timing generator 36A has a function of generating a timing signal for applying the word line overshoot voltage VWLH to the word line WL when a write operation is executed on a memory cell, unlike the timing generator 36 according to the first exemplary embodiment. Other configurations are the same as those illustrated in the block diagram according to the first exemplary embodiment in FIG. 2. In addition, the same circuit configurations as those according to the first exemplary embodiment can be used as the detailed peripheral circuit configurations of the memory cell such as the sense amplifiers SA, except that the word line driver SWD uses the word line overshoot voltage VWLH to drive the word line WL.

### (Operation of Third Exemplary Embodiment)

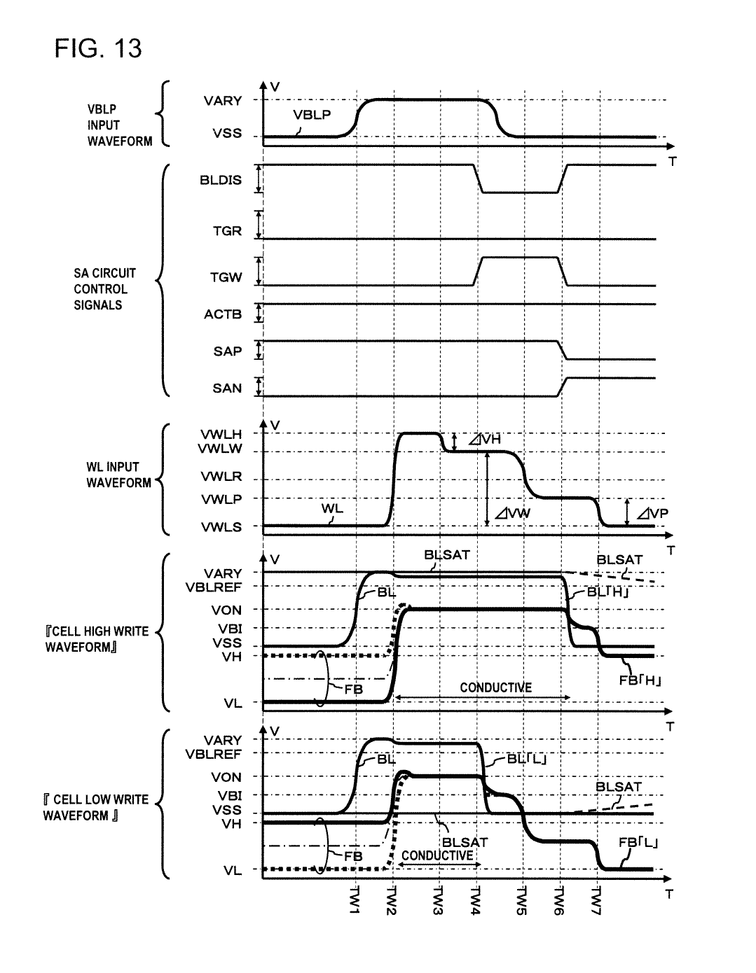

FIG. 13 is a waveform diagram illustrating an operation of writing data in a memory cell according to the third exemplary embodiment. Only the different points between FIG. 13 and FIG. 8, which is a waveform diagram illustrating an operation of writing data in a memory cell according to the first exemplary embodiment, will be described. Repetitive descriptions for the same portions as those in the waveform according to the first exemplary embodiment in FIG. 8 will be omitted.

In FIG. 13, operation timings before timing TW2 are the same as those in FIG. 8. At timing TW2, the word line WL is increased from the word line standby voltage VWLS to the word line overshoot voltage VWLH. The word line overshoot voltage VWLH is higher than the word line write voltage VWLW by a voltage ΔVH. Whether a high or low level is written in the memory cell, the voltage of the FB node is increased by coupling of the capacitor C1.

Particularly, if the memory cell has been holding a low level prior to timing TW1, namely, if the FB node is at the VL level, the voltage of the FB node is increased by coupling to a voltage level higher than the VBI level by the voltage ΔVH at timing TW2. As a result, the thyristor is rapidly brought in a conductive state.

At timing TW3, the word line WL is decreased from the word line overshoot voltage VWLH to the word line write voltage VWLW. After timing TW4. FIG. 13 is the same as the waveform diagram in FIG. 8 illustrating an operation of writing data in a memory cell according to the first exemplary embodiment.

### (Meritorious Effects of Third Exemplary Embodiment)

According to the third exemplary embodiment, as in the first exemplary embodiment, even when a low level is written in a memory cell, the cell is brought in a conductive state from timing TW2 to timing TW4. In addition, since the word line WL is overshot at timing TW2, even when a low level is written in the memory cell, the thyristor can be brought in a conductive state rapidly at timing TW2. In this way, when a memory cell holding low-level data is rewritten with high-level data, the margin can be increased significantly.

When data is written in a memory cell, the word line WL is decreased from the word line overshoot voltage VWLH to the word line write voltage VWLW. Thus, after writing, the voltage VH or VL held by the FB node of the memory cell can be calculated by Expression 1 or 2, as in the first exemplary embodiment. Thus, the third exemplary embodiment provides the same advantageous effects, even if applied to the FBC memory according to the second exemplary embodiment.

### Fourth Exemplary Embodiment

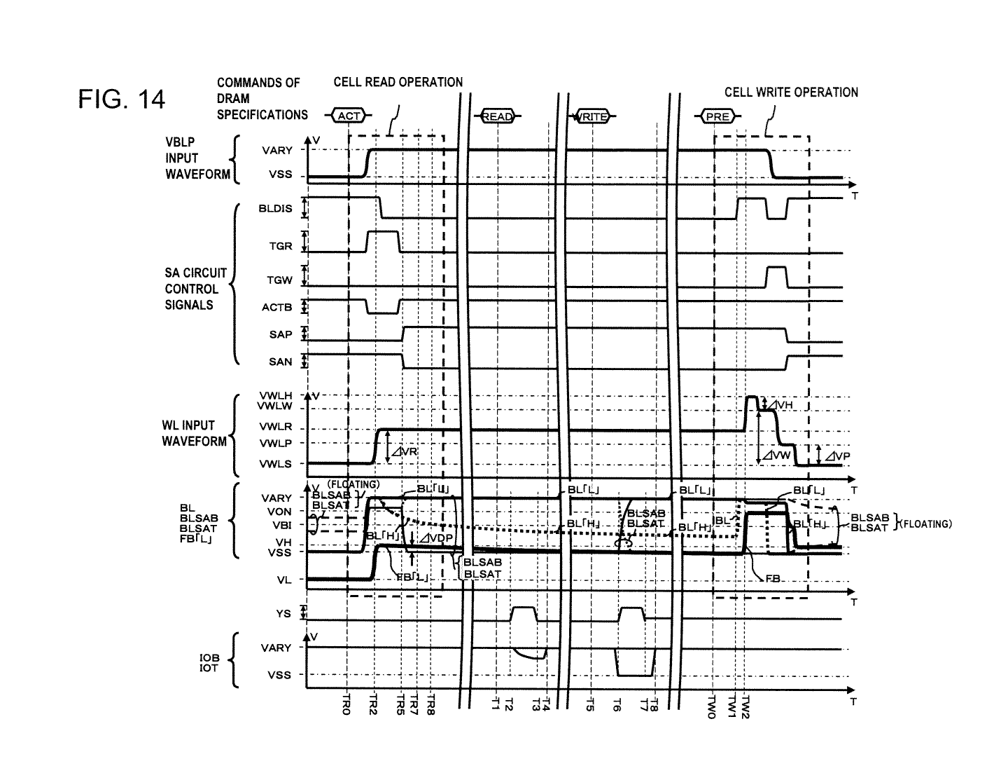

A fourth exemplary embodiment requires less power consumption when an operation compatible with a conventional DRAM such as a DDR SDRAM (Double Data Rate Synchronous DRAM) is executed with the third exemplary embodiment, in which the overshoot voltage is applied to a word line when data is written in a memory cell. FIG. 14 is a waveform diagram illustrating an operation of accessing a memory cell when an operation compatible with DRAM specifications is executed according to the fourth exemplary embodiment.

In FIG. 14, in accordance with an ACT command inputted from the outside, a word line WL is selected by a row address specified, and data is read from a memory cell selected by the word line WL to the flip flop F.F. of a sense amplifier SA. Subsequently, if a READ command is inputted, data read to the flip flop F.F. of the sense amplifier SA by the ACT command is outputted to the outside, based on a specified column address. If a WRITE command is inputted, data held by flip flop F.F. of a sense amplifier SA of a column address specified by data inputted from the outside is updated. The operation at this stage simply updates the data held by the flip flop F.F. of the sense amplifier SA. The memory cell data is updated when a PRE command is executed. When a PRE command is executed, a memory cell corresponding to the row address selected by the ACT command is written with the data held by the flip flop F.F. of the sense amplifier SA. After the ACT command is inputted, during the operation including the sensing at timing TR5 in the memory cell read operation and the input of the READ and WRITE commands, the word line WL selected by the ACT command is maintained at the word line read voltage VWLR. The bit line BL is maintained in a floating state. In addition, from when the ACT command is executed to when the PRE command is executed, the bit line drive power supply signal VBLP is fixed at the voltage VARY.

In a cell write operation after a PRE command is inputted, at timing TW1, the bit line BL is driven from a floating state to the voltage VARY. Next, at timing TW2, the voltage of word line WL selected by the ACT command is set from the word line read voltage VWLR to the word line overshoot voltage VWLH. The subsequent operation is the same as the operation after timing TW3 in FIG. 13 according to the third exemplary embodiment. Namely, the voltage of the hit line BL is decreased to the VSS level, and the voltage of the selected word line WL is decreased to the word line standby voltage VWLS.

In this waveform example, solid lines indicate the waveforms of the bit line BL and the FB node obtained when a low level is read from a memory cell by using an ACT command, data of the flip flop F.F. of a sense amplifier SA is inverted by using a WRITE command, and a high level is written in the memory cell by using a PRE command. A dotted line indicates the waveform of the bit line BL obtained when a high level is read from a memory cell, data of the flip flop F.F. of a sense amplifier SA is inverted by using a WRITE command, and a low level is written in the memory cell by using a PRE command.

The waveform example in FIG. 14 is illustrated assuming that the operation is executed at a low temperature. Thus, the built-in potential VBI is higher than that in the other waveform diagrams including FIG. 9. Accordingly, the voltages VH and VL are higher than those in the other waveform diagrams. Therefore, when the word line WL is increased from the word line standby voltage VWLS to the word line read voltage VWLR at timing TR2, the voltage of the FB “L” is increased to a voltage higher than VSS by ΔVDP, and a forward voltage is applied across the PN diode between the FB node and VSS (cathode) (see FIG. 4A). If the period between ACT and PRE is very long, the voltage of the FB “L” is decreased close to the VSS level by the forward current flowing through the PN diode. Namely, the voltage of the FB “L” drops by ΔVDP during that period.

In this state, after a PRE command is inputted, if the word line WL is increased from the word line read voltage VWLR only to the word line write voltage VWLW at timing TW2, the voltage level of the FB node at timing TW2 is only set to VBI−ΔVDP, which is insufficient to surely bring the memory element (thyristor) in a conductive state without fail. However, according to the fourth exemplary embodiment, at timing TW2 in FIG. 14 the word line WL is increased to the word line overshoot voltage VWLH, which is higher than the word line write voltage VWLW by the voltage ΔVH. Thus, if the voltage ΔVH is set so that ΔVH>ΔVDP, the voltage level of the FB node is influenced by coupling and is increased to a voltage higher than the voltage VBI. As a result, with a sufficiently large margin, the memory element (thyristor) can be brought in a conductive state without fail.

### (Meritorious Effects of Fourth Exemplary Embodiment)

According to the fourth exemplary embodiment, after an ACT command is inputted, the bit line drive power supply signal VBLP is set to the voltage VARY. This voltage VARY is maintained until the next PRE command is inputted. In addition, after the ACT command is inputted, the voltage of the bit line BL is increased to the voltage VARY, and the hit line drive control signal BLDIS is decreased. As a result, the bit line BL is maintained in a floating state until the next PRE command is inputted. In addition, after the ACT command is inputted, the word line WL is set to the word line read voltage VWLR, and this word line read voltage VWLR is maintained until the next PRE command is inputted. Controlled in this way, compared with a method in which a read operation in FIG. 9 is simply executed in accordance with an ACT command inputted from the outside and a write operation in FIG. 13 is executed after a PRE command is inputted, the number of operations of the bit line drive power supply signal VBLP and the number of charge-discharge operations of the word line WL and the bit line BL can be reduced. As a result, the current consumption can be reduced. In addition, by increasing the word line WL to the word line overshoot voltage VWLH at timing TW2, a sufficient margin for a rewrite operation can be assured even at a low temperature.

### Fifth Exemplary Embodiment

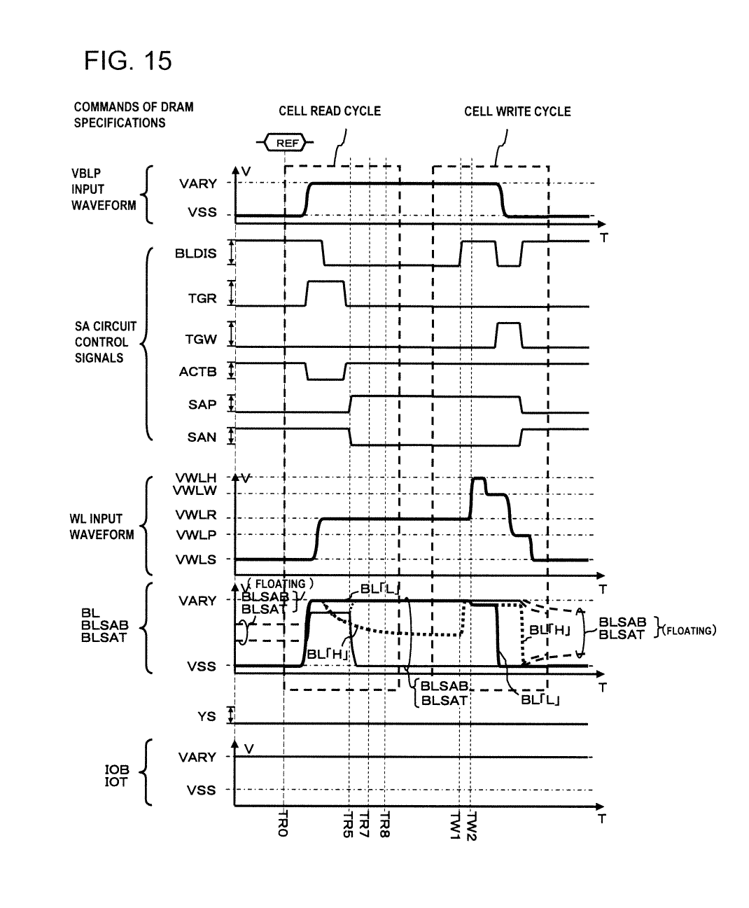

According to a fifth exemplary embodiment, the power consumption during a refresh operation is reduced with the third exemplary embodiment, in which the word line overshoot voltage VWLH is applied to the word line WL when data is written in a memory cell. FIG. 15 is a waveform diagram illustrating a refresh operation with a memory cell according to the fifth exemplary embodiment. In FIG. 15, after a REF (refresh) command is inputted from the outside at timing TR0, data is read to the flip flop F.F. of a sense amplifier SA from a memory cell connected to a word line WL specified based on a row address specified by the refresh control circuit 40 (see FIG. 12) (a cell read cycle). Immediately after the cell read cycle, data amplified by the flip flop F.F. of the sense amplifier SA is written in the memory cell (a cell write cycle).

As illustrated in FIG. 15, according to the fifth exemplary embodiment, in the cell read cycle of a refresh operation, first, the bit line drive power supply signal VBLP is set to the voltage VARY. The voltage VARY is maintained until writing is started in the cell write cycle. In addition, the word line WL is set to the word line read voltage VWLR in the cell read cycle, and the word line WL is maintained at the word line read voltage VWLR until increased to the word line overshoot voltage VWLH in the cell write cycle. In addition, the bit line BL is set to be in a floating state in the cell read cycle, and the bit line BL is maintained in a floating state until the voltage VARY is applied in the cell write cycle.

### (Meritorious Effects of Fifth Exemplary Embodiment)

Compared with a refresh operation in which a read operation in FIG. 9 and a write operation in FIG. 13 are simply executed, the refresh operation according to the fifth exemplary embodiment requires a reduced number of operations of the bit line drive power supply signal VBLP and a reduced number of charge-discharge operations of the word line WL and the bit line BL. Thus, the current consumption during a refresh operation can be reduced.

### Sixth Exemplary Embodiment

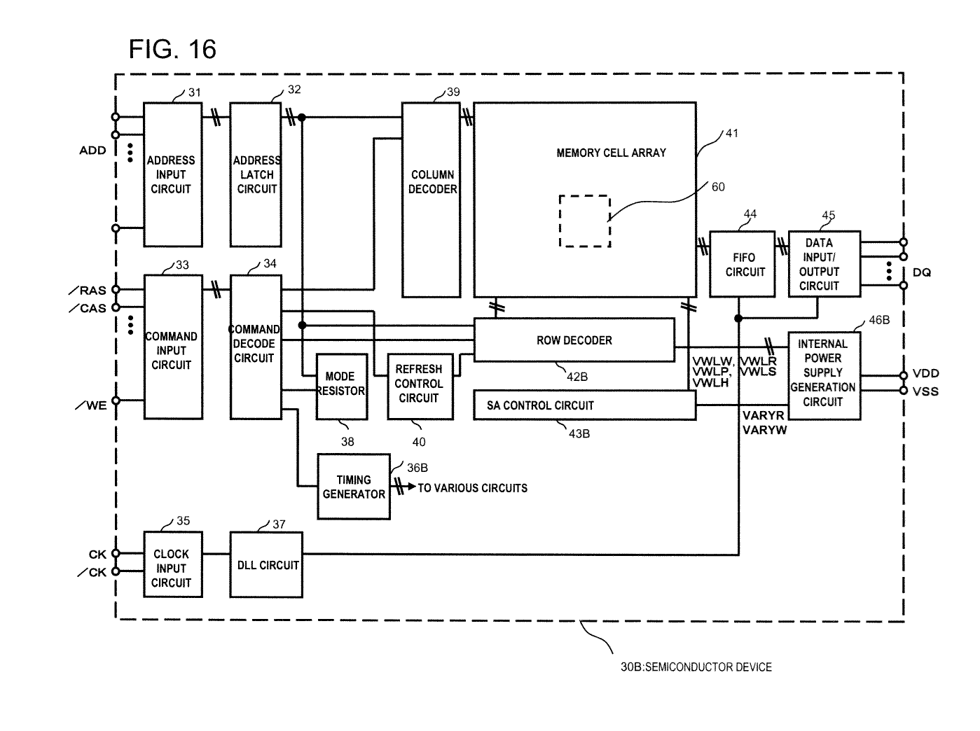

FIG. 16 is a block diagram illustrating an overall configuration of a semiconductor device 30B according to a sixth exemplary embodiment. In FIG. 16, configurations approximately the same as those illustrated in the block diagram of the semiconductor device 30 according to the first exemplary embodiment in FIG. 2 are denoted by the same reference characters, and repetitive descriptions will be omitted. In FIG. 16, an internal power supply generation circuit 46B supplies a sense amplifier control circuit 43B with two types of power supplies VARYR and VARYW. The sense amplifier control circuit 43B supplies the power supplies VARYR and VARYW to the sense amplifier circuit SA when read and write operations are executed, respectively. The sense amplifier circuit SA drives the bit line BL, and the bit line BL is supplied with the power supply of the memory cell. Thus, by changing the power supply voltage of the sense amplifier circuit SA, the power supply voltages during the read and write operations supplied to the memory cell can be optimized. In addition to the word line write voltage VWLW, the word line read voltage VWLR, the word line precharge voltage VWLP, and the word line standby voltage VWLS, the internal power supply generation circuit 46B supplies a word line overshoot voltage VWLH to a row decoder 42B. In addition to the word line write voltage VWLW, the word line read voltage VWLR, the word line precharge voltage VWLP, and the word line standby voltage VWLS, the row decoder 42B uses the word line overshoot voltage VWLH to drive the word line WL.

A timing generator 36B has a function of generating a timing signal for applying the word line overshoot voltage VWLH to the word line WL when a write operation is executed on a memory cell, unlike the timing generator 36 according to the first exemplary embodiment. In addition, the timing generator 36B has a function of controlling the SA control circuit 43B so that the bit line is driven with different voltages when write and read operations are executed. Other configurations are the same as those illustrated in the block diagram according to the first exemplary embodiment in FIG. 2. The memory cell included in the memory cell array 41 in FIG. 16 is the thyristor memory cell 66 (see FIG. 4) described in the first exemplary embodiment.

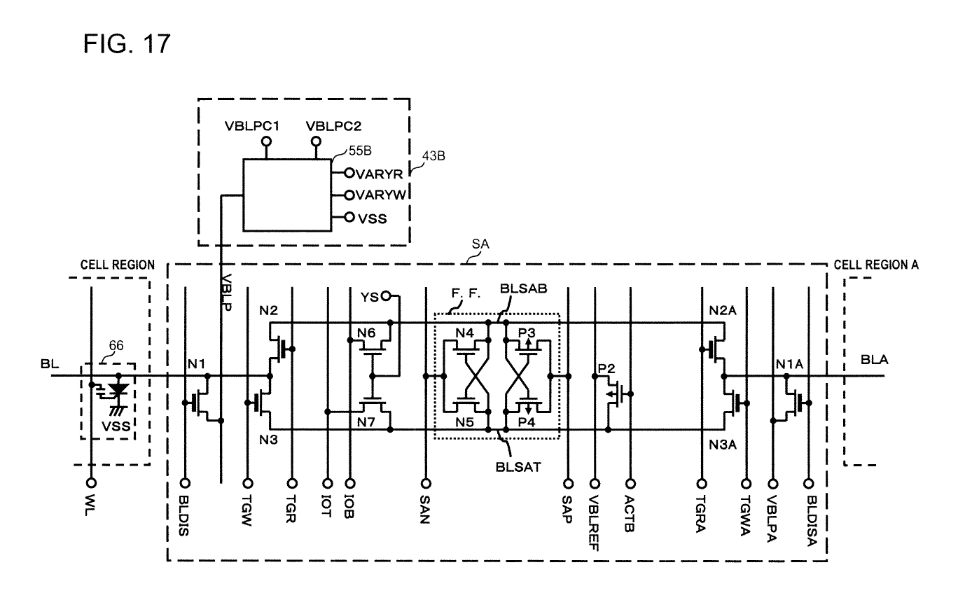

FIG. 17 is a circuit diagram of a sense amplifier and peripheral circuits thereof according to the sixth exemplary embodiment. In FIG. 17, approximately the same configurations as those in the circuit diagram illustrating a sense amplifier and peripheral circuits thereof according to the first exemplary embodiment in FIG. 1 are denoted by the same reference characters, and repetitive descriptions thereof will be omitted. In FIG. 17, the bit line drive power supply signal VBLP is a power supply signal outputted from a bit line drive power supply circuit 55B included in the SA control circuit 43B (see FIG. 16). Based on control signals VBLPC1 and VBLPC2 outputted from the timing generator 36B, the bit line drive power supply circuit 55B selects a power supply signal among the power supplies VARYR, VARYW, and VSS and outputs the selected power supply signal as the bit line drive power supply signal VBLP. As with the case of the bit line drive power supply signal VBLP, similar selection of a power supply signal is executed for a bit line drive power supply signal VBLPA. However, in FIG. 17, illustration of the signal VBLPA is omitted. In addition, different power supply voltages are supplied as the power supply signals SAP and the like of the flip flop F.F. between write and read operations, and illustration of such difference between the voltages is omitted in FIG. 17.

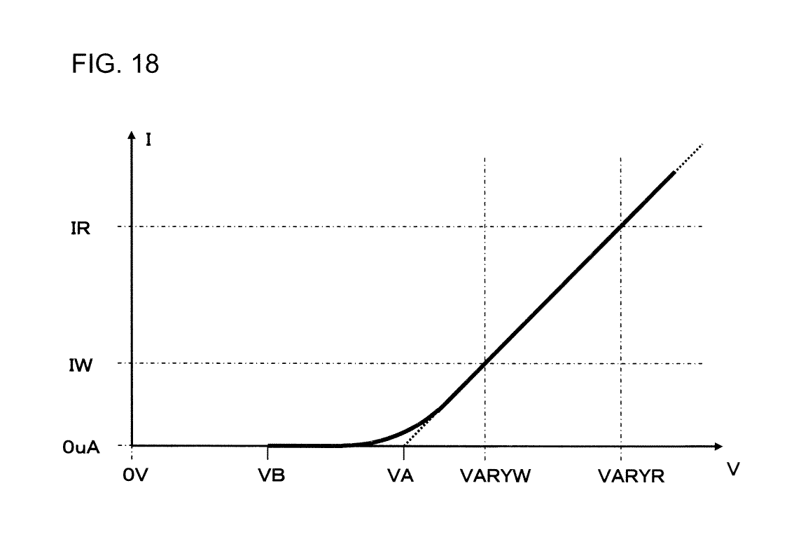

FIG. 18 illustrates voltage-current characteristics when the thyristor of the memory cell 66 (see FIG. 4A) is in a conductive state according to the sixth exemplary embodiment. In FIG. 18, the horizontal axis represents a voltage V between the anode and the cathode and the vertical axis represents a current value I. The characteristics are the same as those of a general thyristor element in a conductive state.

In FIG. 18, when the voltage V between the anode and the cathode is higher than a voltage VA, the current is approximately (V−VA)/R. R represents the internal resistance of the thyristor such as the parasitic resistances r1 to r3 (see FIG. 4A).

When the voltage V between the anode and the cathode is between the voltage VA and a voltage VB, while the NPN bipolar transistor Q1 and the PNP bipolar transistor Q2 are in a conductive state, only a very small current flows. In this state, the current I through the thyristor is exponentially dependent on the voltage V.

When the voltage V between the anode and the cathode is decreased to be lower than the voltage VB, since the bias between the base and the emitter of the NPN bipolar transistor Q1 and the PNP bipolar transistor Q2 is decreased to be small, the amplification factor hFE is decreased to 1 or lower. As a result, the thyristor is brought in a non-conductive state, and the current I stops flowing.

In addition, according to the sixth exemplary embodiment, different voltages are applied to the bit line between read and write operations executed on the memory cell 66. As illustrated in FIG. 18, when the memory cell is in operation, if the voltage VARYW is applied to the bit line BL, a current IW flows through the thyristor of the memory cell 66. If the voltage VARYR is applied to the bit line BL, a current IR flows through the thyristor of the memory cell 66.

### (Operation of Sixth Exemplary Embodiment)

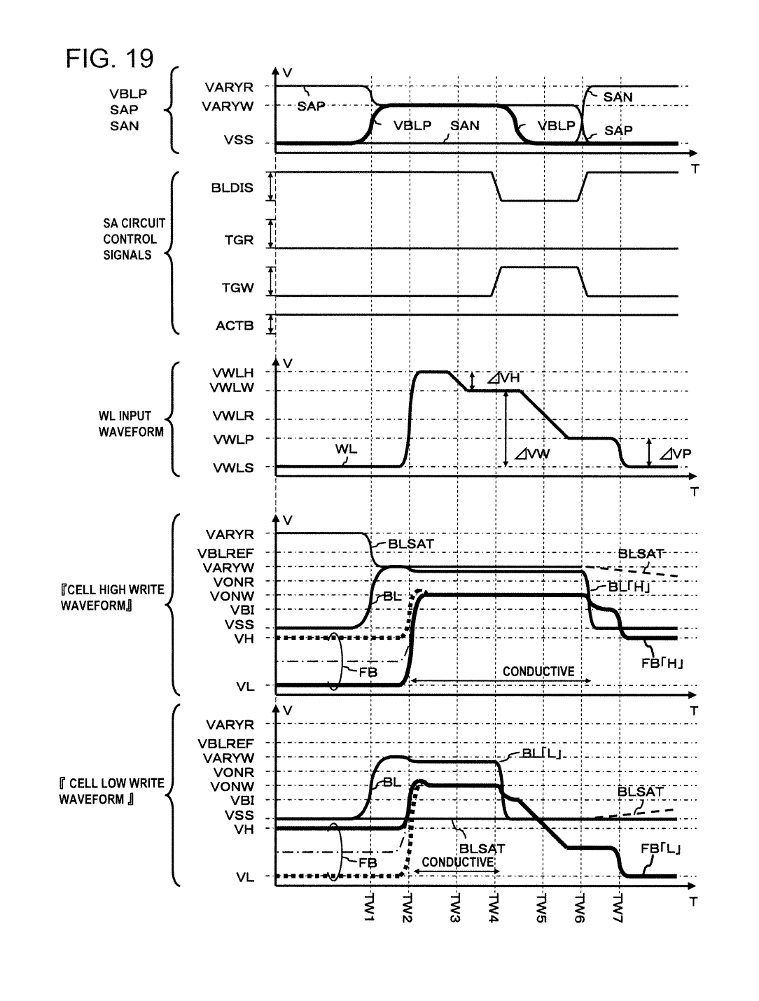

FIG. 19 is a waveform diagram illustrating an operation of writing write data in a memory cell according to the sixth exemplary embodiment. In FIG. 19, only the portions different from those in the waveform diagram illustrating an operation of writing data in a memory cell according to the first exemplary embodiment in FIG. 8 will be described. The portions identical to those according to the first exemplary embodiment in FIG. 8 will not be described repetitively.

An operation of writing data in a memory cell according to the sixth exemplary embodiment will be described with reference to FIGS. 17 and 19. Before timing TW1, the bit line drive control signal BLDIS is set to a high level, and the bit line drive power supply signal VBLP is set to the voltage VSS. The power supplies SAP and SAN of the flip flop F.F. are set to VARYR and VSS, respectively. In this way, the N-type transistor N1 is set in a conductive state, and the bit line BL is supplied with the voltage VSS. In addition, the flip flop F.F. of the SA circuit is activated. The cell write data is latched in advance by the flip flop F.F.

At timing TW1, the bit line drive power supply signal VBLP is changed from the voltage VSS to the voltage VARYW. In addition, the power supply SAP is changed from the VARYR to the voltage VARYW. In this way, the bit line BL “H”/“L” corresponding to the memory cell in which cell High/Low is written is driven from VSS to VARYW via the N-type transistor N1.

At timing TW2, the word line WL is increased from the word line standby voltage VWLS to the word line overshoot voltage VWLH. Whether the cell High or Low write operation, the voltage of the FB node is increased by coupling of the capacitor C1. Since the FB “H” and FB “L” exceed the voltage VBI, the thyristor is brought in a conductive state. Consequently, the FB “H” and the FB “L” are set to a VONW level. Since the voltage of the bit line BL is at the voltage VARYW, the cell current is maintained to be the small current value IW.

At timing TW3, the word line WL is decreased from the word line overshoot voltage VWLH to the word line write voltage VWLW.

At timing TW4, the bit line drive control signal BLDIS is decreased from a high level to a low level, and the control signal TGW is increased from a low level to a high level. In this way, the bit line BL is connected to the non-inverting sense amplifier bit line BLSAT, and the bit line BL “H” corresponding to the cell in which cell High is written is continuously supplied with the voltage VARYW. Thus, since the thyristor is maintained in a conductive state, the current IW continues to flow. However, the voltage of the bit line BL “L” corresponding to the cell in which cell Low is written is changed and supplied with the voltage VSS. Thus, since the thyristor is brought in a conductive state, the voltage of FB “L” is rapidly decreased to the voltage VBI. In addition, by timing TW6, the bit line drive power supply signal VBLP is changed from the voltage VARYW to VSS.

At timing TW5, the word line WL is decreased from the word line write voltage VWLW to the word line precharge voltage VWLP.

At timing TW6, the control signal TGW is decreased, and the bit line drive control signal BLDIS is increased. In addition, the power supply SAP is changed from the voltage VARYW to VSS, and the power supply SAN is changed from the voltage VSS to VARYR.

At timing TW7, the word line WL is changed from the word line precharge voltage VWLP to the word line standby voltage VWLS to end the write operation.

About the cell current IW in the above write operation, the following conditions need to be satisfied.

While the word line WL is decreased at timing TW3 and timing TW5, in both of the cell High and Low write operations, a conductive state needs to be maintained at timing TW3. In the cell High write operation, a conductive state needs to be maintained at timing TW5, too. Namely, while the voltage of the word line WL is decreased, the voltage of the FB node needs to be maintained at approximately the VONW level.

For example, if the voltage change rate of the word line WL is −0.5V/10 ns and the value of the capacitor C1 (see FIG. 4A) is 5 fF, the current value flowing through the FB node via the capacitor C1 is −0.25 uA (=5 fF×(−0.5V/10 ns)). Thus, to maintain the FB node at approximately the VONW level, the collector current of the PNP bipolar transistor Q2 (current flowing through the parasitic resistance r2 in FIG. 4A) needs to be approximately +0.25 uA or more. Based on a general expression for a bipolar current, the collector current supply performance=emitter current×hFE/(fFE+1). Since the current amplification factor hFE of the PNP bipolar transistor Q2 configured as illustrated in FIG. 4A is a value several times greater from a commonsense standpoint, the collector current supply performance of the PNP bipolar transistor Q2 is approximately equal to the emitter current of the PNP bipolar transistor Q2, namely, to the current IW of the thyristor. Thus, since the cell current IW flowing when a cell write operation is executed needs to be approximately 0.25 uA or more, the voltage VARYW needs to be set to obtain that current value.

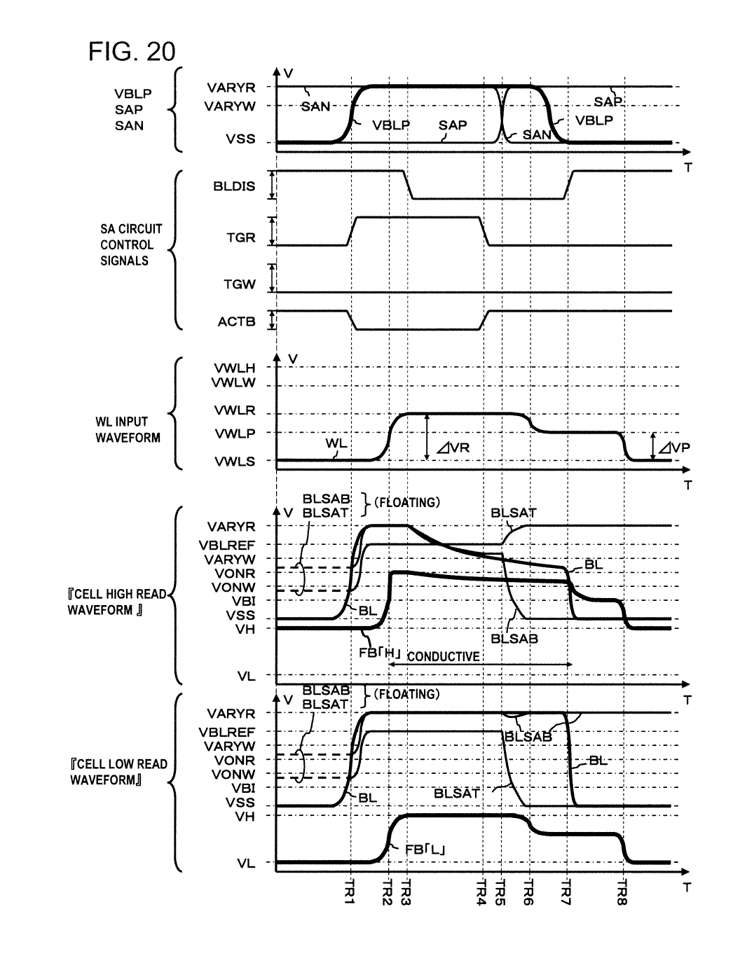

FIG. 20 is a waveform diagram illustrating an operation of reading data from a memory cell according to the sixth exemplary embodiment. In FIG. 20, only the different points from those in the waveform diagram in FIG. 9 illustrating an operation of reading data from a memory cell according to the first exemplary embodiment will be described. The portions identical to those according to the first exemplary embodiment in FIG. 9 will not be described repetitively.

An operation of reading data from a memory cell according to the sixth exemplary embodiment will be described with reference to FIGS. 17 and 20. Before timing TR1, the bit line drive control signal BLDIS is set to a high level, the bit line drive power supply signal VBLP is set to the voltage VSS, and the power supply SAN is set to the level VARYR. In this state, the N-type transistor N1 is in a conductive state, and the bit line BL is supplied with the voltage VSS.

At timing TR1, the bit line drive power supply signal VBLP is changed from the voltage VSS to the voltage VARYR, the control signal TGR rises from a low level to a high level, and the read control signal ACTB falls from a high level to a low level. In this way, whether the bit line BL is “H” or “L”, the bit line BL is driven from the voltage VSS to the voltage VARYR via the N-type transistor N1. In addition, the inverting sense amplifier bit line BLSAB is electrically connected to the bit line BL via the N-type transistor N2, and the non-inverting sense amplifier bit line BLSAT is supplied with the bit line reference voltage VBLREF via the P-type transistor P2.

At timing TR2, the word line WL is increased from the word line standby voltage VWLS to the word line read voltage VWLR. Simultaneously, the voltage of the FB node is increased by coupling of the capacitor C1. In addition, the FB “H” (cell High) exceeds the built-in potential VBI level and the memory element is brought in a conductive state. On the other hand, since the FB “L” (cell Low) does not reach the built-in potential VBI level, the memory element is maintained in a non-conductive state.

At timing TR3, the bit line drive control signal BLDIS is decreased from a high level to a low level. Accordingly, since the N-type transistor N1 is brought in a non-conductive state, the supply of the voltage VARYR to the bit line BL is stopped. After timing TR3, if the thyristor is in a conductive state, namely, in the case of a cell High operation, the voltage of the bit line BL is decreased in accordance with the voltage V-current I characteristics in FIG. 18. In this case, since the voltage VARYR is a high voltage, the cell current value IR is also large, and the voltage drop rate of the bit line BL is high. If the thyristor is in a non-conductive state, namely, in the case of a cell Low operation, since no current flows through the memory cell from the bit line, the voltage of the bit line BL is maintained at approximately the voltage VARYR. In addition, after timing TR3, the voltage of the bit line drive power supply signal VBLP is decreased from the voltage VARYR to the voltage VSS until timing TR7.

At timing TR4, the control signal TGR is decreased from a high level to a low level, and the read control signal ACTB is increased from a low level to a high level.

At timing TR5, the power supply SAN is changed from the voltage VARYR to voltage VSS, and the power supply SAP is changed from the voltage VSS to the voltage VARYR. The subsequent operation is not particularly different from the read operation illustrated in FIG. 9, except that the voltage VARYR is used, instead of the voltage VARY.

Thus, the voltage VARYR of the bit line BL used in a cell read operation is higher than the voltage VARYW of the bit line BL used in a cell write operation. Since the voltage of the bit line BL “H” corresponding to a cell in which cell High is written is rapidly decreased, the wait period between timing TR3 and timing TR4 can be shortened. As a result, a cell read operation can be executed at high speed.

### (Meritorious Effects of Sixth Exemplary Embodiment)

According to the sixth exemplary embodiment, by applying a different voltage to the bit line BL depending on the operation (a cell write operation or a cell read operation), each of the write and read operations can be optimized. In particular, when the memory cell is a thyristor memory, by setting the bit line voltage VARYW used when a cell write operation is executed to be lower than bit line voltage VARYR used when a cell read operation is executed, less power is required when a write operation is executed, and a faster operation can be executed when a read operation is executed.

After a cell write operation, when write data represents high and low levels, the FB node represents the voltages VH and VL based on Expressions 1 and 2, respectively. The bit line voltage VARYW has little impact on the FB node when a cell write operation is executed. Similarly, the hit line voltage VARYR has little impact on the voltage of the FB node after a cell read operation is executed.

### Seventh Exemplary Embodiment

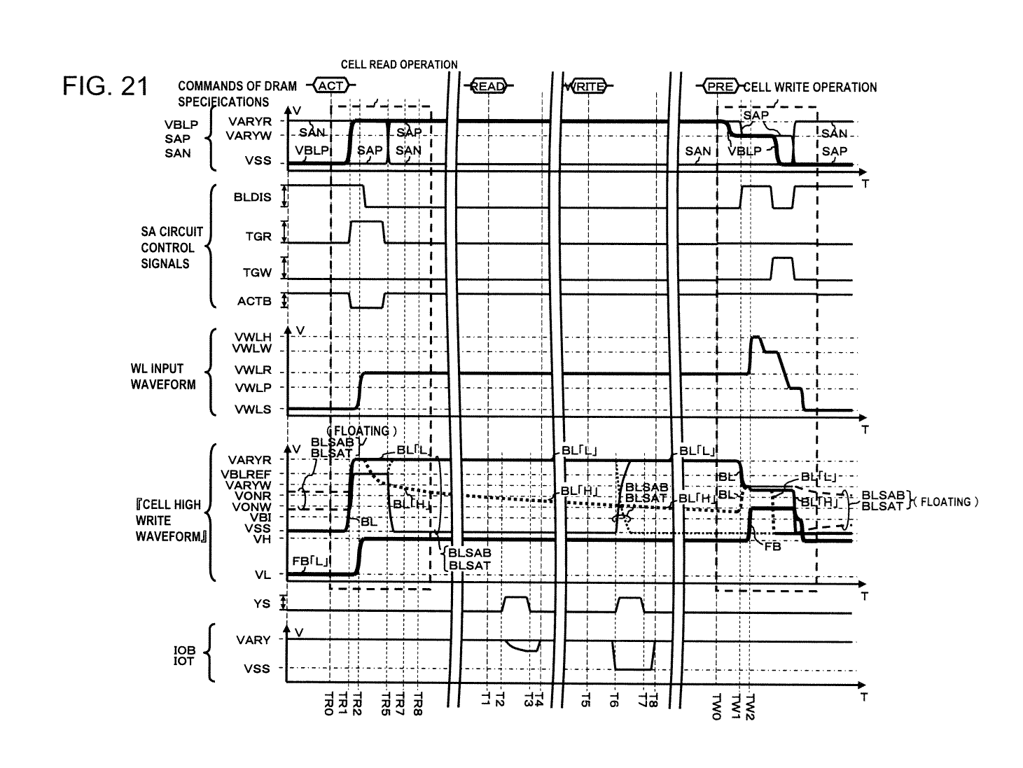

A seventh exemplary embodiment requires less power consumption when an operation compatible with a conventional DRAM such as a DDR SDRAM (Double Data Rate Synchronous DRAM) is executed with the sixth exemplary embodiment, in which optimum bit line voltages are applied when data is written in a memory cell and when data is read from a memory cell. FIG. 21 is a waveform diagram illustrating an operation of accessing a memory cell when an operation compatible with DRAM specifications is executed according to the seventh exemplary embodiment.

In FIG. 21, in accordance with an ACT command inputted from the outside, a word line WL is selected by a row address specified, and data is read from a memory cell selected by the word line WL to the flip flop F.F. of a sense amplifier SA. Subsequently, if a READ command is inputted, data read to the flip flop F.F. of the sense amplifier SA by the ACT command is outputted to the outside, based on a specified column address. If a WRITE command is inputted, data held by the flip flop F.F. of a sense amplifier SA of a column address specified by data inputted from the outside is updated. The operation at this stage simply updates the data held by the flip flop F.F. of the sense amplifier SA. The memory cell data is updated when a PRE command is executed later.

When a PRE command is executed, the data held by the flip flop F.F. of the sense amplifier SA in a memory cell corresponding to the row address selected by the ACT command is written with data. After the ACT command is inputted, during the operation including the sensing at timing TR5 in the memory cell read operation and the input of the READ and WRITE commands, the word line WL selected by the ACT command is maintained at the word line read voltage VWLR. The bit line BL is maintained in a floating state. In addition, from when the ACT command is executed to when the PRE command is executed, the bit line drive power supply signal VBLP is fixed at the voltage VARYR.

In a cell write operation after a PRE command is inputted, at timing TW1, the bit line BL is driven from a floating state to the voltage VARYW. Next, at timing TW2, the voltage of the word line WL selected by the ACT command is set from the word line read voltage VWLR to the word line overshoot voltage VWLH. The subsequent operation is the same as the operation after timing TW3 in FIG. 13 according to the third exemplary embodiment. Namely, the voltage of the bit line BL is decreased to the VSS level, and the voltage of the selected word line WL is decreased to the word line standby voltage VWLS.

### (Meritorious Effects of Seventh Exemplary Embodiment)

According to the seventh exemplary embodiment, when an ACT command is inputted and data is read from a memory cell to the flip flop F.F. of a sense amplifier SA, the voltage of the bit line is set to the high level VARYR. Thus, the data can be read from the memory cell at high speed. In addition, when a PRE command is inputted and data is written in a memory cell from the flip flop F.F. of a sense amplifier SA, the low bit line voltage VARYW is used. Thus, power for writing can be reduced.

Further, once the bit line drive power supply signal VBLP is set to the voltage VARYR after an ACT command is inputted, the bit line drive power supply signal VBLP is maintained at the voltage VARYR until a PRE command is inputted next. In addition, after an ACT command is inputted, once the voltage of the bit line BL is increased to the voltage VARYR and the bit line drive control signal BLDIS is decreased, the voltage of the bit line BL is maintained in a floating state until a PRE command is inputted. In addition, after an ACT command is inputted, once the word line WL is set to the word line read voltage VWLR, the word line WL is maintained at this level until a PRE command is inputted next. In addition, the power supply SAP for the p-type transistors of the flip flop F.F. of the sense amplifier SA maintains the voltage VARYR from when an ACT command is inputted at timing TR5 to when the memory cell rewrite operation is ended after a PRE command is inputted. Controlled in this way, compared with a method in which a read operation in FIG. 20 is simply executed in accordance with an ACT command inputted from the outside and a write operation in FIG. 19 is executed after a PRE command is inputted, the number of operations of the bit line drive power supply signal VBLP and the number of charge-discharge operations of the word line WL and the bit line BL can be reduced. As a result, the current consumption can be reduced.

### Eighth Exemplary Embodiment

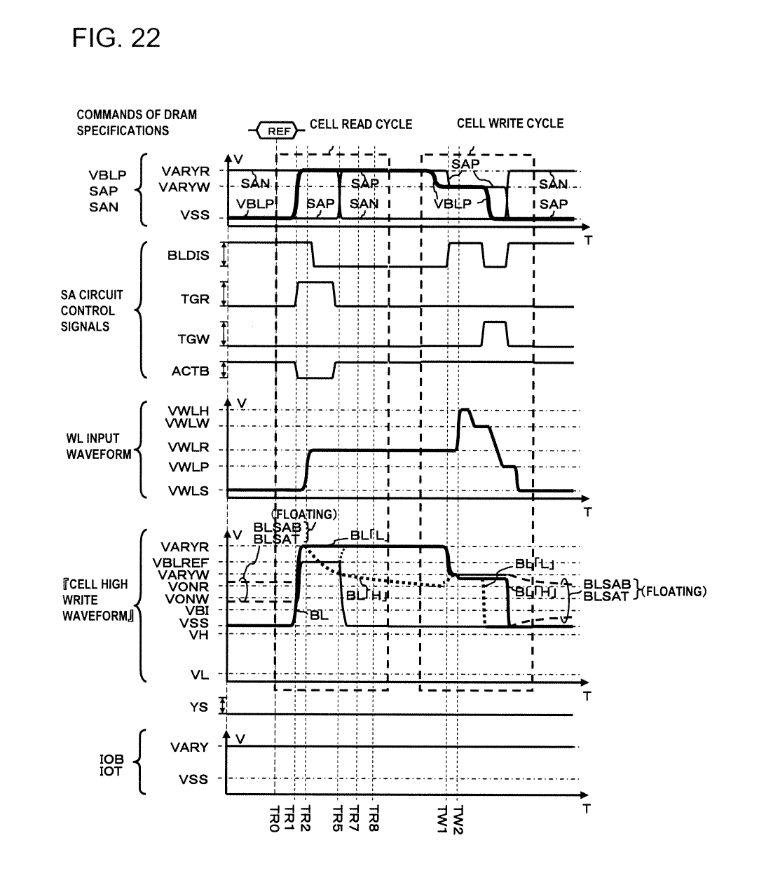

According to an eighth exemplary embodiment, the power consumption during a refresh operation is reduced with the sixth exemplary embodiment, in which optimum bit line voltages are applied when data is written in a memory cell and when data is read from a memory cell. FIG. 22 is a waveform diagram illustrating a refresh operation with a memory cell according to the eighth exemplary embodiment. In FIG. 22, after a REF (refresh) command is inputted from the outside at timing TR0, data is read to the flip flop F.F. of a sense amplifier SA from a memory cell connected to a word line WL specified based on a row address specified by the refresh control circuit 40 (see FIG. 16) (a cell read cycle). Immediately after the cell read cycle, data amplified by the flip flop F.F. of the sense amplifier SA is written in the memory cell (a cell write cycle).

As illustrated in FIG. 22, according to the eighth exemplary embodiment, in the cell read cycle of a refresh operation, first, the bit line drive power supply signal VBLP is set to the voltage VARYR. The voltage VARYR is maintained until writing is started in the cell write cycle. Similarly, the power supply SAP for the P-type transistors of the flip flop F.F. of the sense amplifier SA maintains the voltage VARYR. In the cell write cycle, the voltages of the bit line drive power supply signal VBLP and the power supply SAP are decreased to the voltage VARYW to execute writing.

In addition, the word line WL is set to the word line read voltage VWLR in the cell read cycle, and the word line WL is maintained at the word line read voltage VWLR until increased to the word line overshoot voltage VWLH in the cell write cycle. In addition, the bit line BL is set to be in a floating state in the cell read cycle, and the bit line BL is maintained in a floating state until the voltage VARYW is applied in the cell write cycle.

### (Meritorious Effects of Eighth Exemplary Embodiment)

According to the eighth exemplary embodiment, compared with a method in which a read operation in FIG. 20 is simply executed in accordance with an ACT command inputted from the outside and a write operation in FIG. 19 is executed after a PRE command is inputted, the refresh operation according to the eighth exemplary embodiment requires a reduced number of operations of the bit line drive power supply signal VBLP and a reduced number of charge-discharge operations of the word line WL and the bit line BL. Thus, the current consumption during a refresh operation can be reduced.

In addition, in accordance with rates of refresh specifications, by setting the voltages, which are applied to the bit line in the cell read and write cycles of a refresh operation, to be optimum voltages different from those (in the read and write cycles based on ACT and PRE commands, respectively) according to the sixth or seventh exemplary embodiment, the current consumption during the refresh operation can be reduced further.

The meritorious effects of the present disclosure, particularly with respect to certain exemplary embodiments, are summarized as follows. According to each aspect of the present disclosure, when data is written in a memory cell, a control circuit selects a bit line and a word line, brings the memory cell in a conductive state irrespective of the level of the write data, and sets the bit line to a voltage level based on the write data to write the data in the memory cell. Thus, without an active element as a trigger element, conductive and non-conductive states of the memory cell can be accurately controlled. According to the present disclosure, the following modes are further possible, but not limitative thereto.

### Mode 1

A semiconductor device may comprise:

a memory cell comprising: a capacitative element having one end connected to a word line; and a thyristor having an anode connected to a bit line, a cathode connected to a reference potential, and a gate connected to the other end of the capacitative element;
wherein, when data is read from the memory cell, a voltage having a different selection level from a voltage applied when data is written in the memory cell is applied to the bit line.

### Mode 2

A semiconductor device may comprise:

a memory cell comprising: a capacitative element having one end connected to a word line; and a thyristor having an anode connected to a bit line, a cathode connected to a reference potential, and a gate connected to the other end of the capacitative element;
wherein, when data is read from the memory cell, a voltage exceeding a voltage applied to the bit line when data is written in the memory cell is applied to the bit line.

### Mode 3

The semiconductor device according to mode 1 or 2;

wherein the voltage applied to the bit line when data is written in the memory cell is set so that a current equal to or greater than a current flowing through the gate from the capacitative element as a word line is decreased can be supplied to the gate from the bit line via the and
wherein, when data is read from the memory cell, a voltage equal to or greater than the voltage is applied to the bit line.

### Mode 4

A semiconductor device may comprise:

a plurality of word lines;
a plurality of bit lines extending in a direction intersecting the word lines;
a plurality of memory cells arranged at intersections of the plurality of hit lines and the plurality of word lines in a matrix, each of the memory cells comprising: a capacitative element having one end connected to a corresponding one of the plurality of word lines; and a thyristor element having an anode connected to a corresponding one of the plurality of bit lines, a cathode connected to a reference potential, and a gate connected to the other end of the capacitative element;
wherein, when data is read from the plurality of memory cells, a voltage having a different selection level from a voltage applied when data is written in the memory cells to be read is applied to the plurality of bit lines.

### Mode 5

A semiconductor device according to mode 4, may further comprise:

a plurality of word line drivers, each of which is arranged for a corresponding one of the plurality of word lines and drives corresponding word line based on a row address specified from the outside; and
a plurality of sense amplifier circuits, each of which is connected to a corresponding one of the plurality of bit lines, has a flip-flop circuit, amplifies a signal of a corresponding bit line read from a memory cell and temporarily storing data in the flip-flop circuit when a read operation is executed, and drives a corresponding bit line based on data temporarily stored in the flip-flop circuit when a write operation is executed;
wherein, when an active command is given in synchronization with a system clock from the outside and the row address is specified, the plurality of bit lines are set to a first voltage value associated with the read operation, a power supply voltage of the flip-flop circuits included in the plurality of sense amplifier circuits is set to the first voltage value, a word line specified by the row address is selected from the plurality of word lines, data is read from corresponding memory cells among the plurality of memory cells, and data is temporarily stored in corresponding flip-flop circuits among the plurality of flip-flop circuits;
wherein, between when the active command is given and when a precharge command is subsequently given, the power supply voltage of the plurality of flip-flop circuits maintains the first voltage value, if a read command is given in this period, data temporarily stored in flip-flop circuits specified by a column address among the plurality of flip-flop circuits is outputted to the outside, and if a write command is given in this period, data temporarily stored in flip-flop circuits specified by a column address among the plurality of flip-flop circuits is updated by data inputted from the outside; and
wherein, when the precharge command is given, the power supply voltage value of the plurality of flip-flops is changed to a second voltage value associated with the write operation, the bit lines are driven to the second voltage value, and data temporarily stored in the plurality of flip-flops is written in the corresponding memory cells.

### Mode 6

The semiconductor device according to mode 5;

wherein, when a refresh operation is executed, the plurality of bit lines may be set to a third voltage value associated with a refresh read operation, the power supply voltage of the flip-flop circuits included in the plurality of sense amplifier circuits is set to the third voltage value, a word line specified by a refresh address specified by a refresh control circuit is selected from the plurality of word lines, data is read from corresponding memory cells of the plurality of memory cells, and the data is temporarily stored in the corresponding flip-flop circuits; and wherein, when a refresh operation is executed, the power supply voltage value of the plurality of flip-flops may be changed to a fourth voltage value associated with a refresh write operation, the bit lines are driven to the fourth voltage value, and data temporarily stored in the plurality of flip-flops is written in the corresponding memory cells.

### Mode 7

A semiconductor device may comprise:

a memory cell comprising: a capacitative element having one end connected to a word line; and a thyristor having an anode connected to a bit line, a cathode connected to a reference potential, and a gate connected to the other end of the capacitative element; and
a control circuit bringing, when a first data is written in the memory cell, the thyristor in a conductive state before bringing the thyristor in a non-conductive state, wherein when the first data is read from the memory cell, the thyristor keeps in the non-conductive state.

### Mode 8

A semiconductor device may comprise:

a memory cell comprising: a capacitative element having one end connected to a word line; and a switch element having a first node connected to a bit line, a second node connected to a reference potential, and a floating body, which is brought in a floating state when data is held, connected to the other end of the capacitative element; and
a control circuit bringing, when a first data is written in the memory cell, the switch element in a conductive state before bringing the switch element in a non-conductive state, wherein when the first data is read from the memory cell, the switch element keeps in the non-conductive state.

Modifications and adjustments of the exemplary embodiments and examples are possible within the scope of the overall disclosure (including the claims and the drawings) of the present invention and based on the basic technical concept of the present invention. Various combinations and selections of various disclosed elements are possible within the scope of the claims of the present invention. That is, the present invention of course includes various variations and modifications that could be made by those skilled in the art according to the overall disclosure including the claims and the drawings and based on the technical concept.

What is claimed is:

1. A semiconductor device, comprising:
a bit line;
a memory cell including a switch circuit coupled to the bit line and a memory element configured to store either one of first and second data; and
a control circuit controlling a voltage of the bit line to turn on the switch element in a first time period and to turn off the switch element in a second time period following the first time period when the control circuit writes the first data to the memory element, and controlling the voltage of the bit line to turn on the switch element in with the first time period and to maintain an on-state of the switch circuit in the second time period when the control circuit writes the second data to the memory element.

2. The semiconductor device according to claim 1, wherein the switch circuit comprises a thyristor that includes an anode coupled to the bit line, a gate coupled to the memory element and a cathode coupled to a voltage terminal.

3. The semiconductor device according to claim 2, wherein the voltage terminal is supplied with a ground potential.

4. The semiconductor device according to claim 1, wherein the switch circuit comprises a bipolar transistor that includes a gate coupled to the memory element and collector and emitter, one of the collector and emitter being coupled to the bit line, and the other of the collector and emitter being coupled to a voltage terminal.

5. The semiconductor device according to claim 4, wherein the voltage terminal is supplied with a ground potential.

6. The semiconductor device according to claim 1, wherein the control circuit controls the bit line to be supplied with a first voltage in the first time period and a second voltage in the second time period when the control circuit writes the first data to the memory element and supplied with the first voltage in the first time period and a third voltage in the second time period when the control circuit writes the second data to the memory element, the third voltage being greater than the second voltage.

7. The semiconductor device according to claim 6, wherein the third voltage is substantially equal to the first voltage.

8. The semiconductor device according to claim 1, further comprising a word line coupled to the control circuit and the memory element of the memory cell.

9. The semiconductor device according to claim 8, wherein the control circuit controls the word line to be supplied with a fourth voltage in both first and second time periods.

10. A semiconductor device, comprising:
a bit line;
a word line; and
a memory cell having a first terminal connected to the bit line and a second terminal connected to the word line;
wherein, when data is written in the memory cell, irrespective of whether the write data represents first or second data, the memory cell is brought in a conductive state in a first period by setting the bit line to a first voltage level.

11. The semiconductor device according to claim 10;
wherein the memory cell comprises:
a third terminal connected to a reference potential;
a capacitative element having one end connected to the second terminal; and
a switch element having a floating body that is connected to the other end of the capacitative element and that is brought in a floating state when data is held and controlling a current flowing between the first terminal and the third terminal based on a voltage change amount applied to the floating body from the second terminal via the capacitative element.

12. The semiconductor device according to claim 10;
wherein the memory cell comprises:
a third terminal connected to a reference potential;
a capacitative element having one end connected to the second terminal; and
a thyristor element comprising an anode connected to the first terminal, a cathode connected to the third terminal, and a gate connected to the other end of the capacitative element.

13. The semiconductor device according to claim 10;
wherein, when the write data represents the first data, in a second period after the first period, the voltage level of the bit line is set to a second voltage level corresponding to the first data, and when the write data represents the second data, in the second period, the voltage level of the bit line is set to a third voltage level corresponding to the second data, the second and third voltage levels being different from each other.

14. The semiconductor device according to claim 13;
wherein the second voltage level is higher than the third voltage level.

15. The semiconductor device according to claim 13;
wherein the first voltage level is substantially equal to the second voltage level.

16. The semiconductor device according to claim 13;
wherein the word line is in a non-selected state before the first period and is set to a selected state in the first period, and a fourth voltage level applied in an initial period of the first period is higher than a fifth voltage level applied in a subsequent period.

17. The semiconductor device according to claim 13;
wherein, when the written data in the memory cell is read out from the memory cell, the bit line is charged by a sixth voltage level higher than the second voltage level.

18. The semiconductor device according to claim 17, further comprising:
a sense amplifier connected to the bit line;
wherein, in the read operation, when the potential of the bit line is changed from the charging sixth voltage level to a level lower than a reference level, the sense amplifier determines that the write data represents the first data, and when the potential of the bit line is changed to a level higher than the reference level, the sense amplifier determines that the write data represents the second data.
